(19) United States
(12) Patent Application Publication
(10) Pub. No.: US 2025/0357333 A1
(43) Pub. Date: Nov. 20, 2025

(54) METALLIZATION STACKS WITH STAGGERED CONDUCTIVE LINES

(71) Applicant: Intel Corporation, Santa Clara, CA (US)

(72) Inventor: Mrugesh R. Shah, Austin, TX (US)

(73) Assignee: Intel Corporation, Santa Clara, CA (US)

(21) Appl. No.: 18/667,340

(22) Filed: May 17, 2024

(51) Int. Cl. H01L 23/528; H01L 23/522

(52) U.S. Cl. CPC H01L 23/528; H01L 23/5226

(57) ABSTRACT

Integrated circuit (IC) structures and related semiconductor devices including metallization stacks having metallization layers with staggered conductive lines, as well as methods of fabricating such IC structures, are disclosed. An example IC structure includes a first metallization layer with a first conductive line, a second metallization layer with a second conductive line, and a third metallization layer with a third conductive line. The first, second, and third metallization layers are stacked along a direction. The second metallization layer is between the first and third metallization layers. A projection of the first conductive line onto a plane perpendicular to the direction is offset with respect to a projection of the third conductive line onto the plane. A projection of the second conductive line onto the plane intersects the projection of the first conductive line onto the plane and the projection of the third conductive line onto the plane.

### BACKGROUND

For the past several decades, the scaling of features in integrated circuits (ICs) has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for the ever-increasing capacity, however, is not without issue. The necessity to optimize the performance of each device and each interconnect becomes increasingly significant.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 is a cross-sectional side view of an IC device that may include a metallization stack having metallization layers with staggered conductive lines, in accordance with various embodiments.

FIG. 2A is an isometric view of a first example of an IC device including a metallization stack having metallization layers with staggered conductive lines, in accordance with some embodiments.

FIG. 2B is a cross-sectional view of the IC device shown in FIG. 2A.

FIG. 2C is a view of a plane including projections of staggered conductive lines shown in the cross-sectional view of FIG. 2B.

FIG. 2D is a cross-sectional view of the IC device shown in FIG. 2A.

FIG. 2E is a view of a plane including projections of staggered conductive lines shown in the cross-sectional view of FIG. 2D.

FIG. 3 is a flow diagram of an example method for providing an IC device that includes a metallization stack having metallization layers with staggered conductive lines, in accordance with some embodiments.

FIGS. 4A-4I illustrate isometric views at various stages in the manufacture of an example IC device that includes a metallization stack having metallization layers with staggered conductive lines according to the method of FIG. 3, in accordance with some embodiments.

FIG. 5A is an isometric view of a second example of an IC device including a metallization stack having metallization layers with staggered conductive lines, in accordance with some embodiments.

FIG. 5B is a cross-sectional view of the IC device shown in FIG. 5A.

FIG. 5C is a view of a plane including projections of staggered conductive lines shown in the cross-sectional view of FIG. 5B.

FIG. 5D is a cross-sectional view of the IC device shown in FIG. 5A.

FIG. 5E is a view of a plane including projections of staggered conductive lines shown in the cross-sectional view of FIG. 5D.

FIG. 6A is an isometric view of a third example of an IC device including a metallization stack having metallization layers with staggered conductive lines, in accordance with some embodiments.

FIG. 6B is a cross-sectional view of the IC device shown in FIG. 6A.

FIG. 6C is a view of a plane including projections of staggered conductive lines shown in the cross-sectional view of FIG. 6B.

FIG. 6D is a cross-sectional view of the IC device shown in FIG. 6A.

FIG. 6E is a view of a plane including projections of staggered conductive lines shown in the cross-sectional view of FIG. 6D.

FIGS. 7A and 7B are top views of a wafer and dies that may include one or more metallization stacks having metallization layers with staggered conductive lines, in accordance with various embodiments.

FIG. 8 is a cross-sectional side view of an IC package that may include one or more metallization stacks having metallization layers with staggered conductive lines, in accordance with various embodiments.

FIG. 9 is a cross-sectional side view of an IC device assembly that may include one or more metallization stacks having metallization layers with staggered conductive lines, in accordance with various embodiments.

FIG. 10 is a block diagram of an example computing device that may include one or more metallization stacks having metallization layers with staggered conductive lines, in accordance with various embodiments.

### DETAILED DESCRIPTION

The systems, methods, and devices of this disclosure each have several innovative aspects, no single one of which is solely responsible for all of the desirable attributes disclosed herein. Details of one or more implementations of the subject matter described in this specification are set forth in the description below and the accompanying drawings.

For purposes of illustrating metallization stacks having metallization layers with staggered conductive lines as described herein, it might be useful to first understand phenomena that may come into play during IC fabrication. The following foundational information may be viewed as a basis from which the present disclosure may be properly explained. Such information is offered for purposes of explanation only and, accordingly, should not be construed in any way to limit the broad scope of the present disclosure and its potential applications.

Front-end-of-line (FEOL) and back-end-of-line (BEOL) are two distinct stages in semiconductor manufacturing (e.g., in advanced complementary metal-oxide-semiconductor (CMOS) processes), each playing an important role in the fabrication of IC structures (or, more generally, of semiconductor devices). These terms refer to the chronological order of processes involved in creating an IC structure. The FEOL processes occur at the front or early stages of semiconductor manufacturing, typically on the surface of a semiconductor (e.g., silicon) wafer. In the FEOL, individual semiconductor device components (e.g., transistor, capacitors, resistors, etc.) can be patterned in a wafer. In the BEOL, interconnect structures such as conductive lines and conductive vias, separated as needed by an insulator material, can be formed to provide electrical connectivity between various components. The BEOL usually starts with forming a first metallization layer on the wafer. The first metallization layer is often called M0. Additional metallization layers can be formed on top of M0, and these metallization layers are often called M1, M2, and so on. In this context, the term “metallization stack” may be used to describe a stack of metallization layers, where each metallization layer may include a conductive line (also sometimes referred to as a “trench,” a “trace,” or a “metal line”) and/or a conductive via (also sometimes referred to as a “metal via”). Conductive lines of a metallization layer are interconnects configured for transferring signals and power along electrically conductive (e.g., metal) structures extending in the x-y plane (e.g., in the x or y directions) of example coordinate systems shown in the present drawings, while the conductive vias of a metallization layer are configured for transferring signals and power through electrically conductive structures extending in the z-direction, e.g., to any of the adjacent metallization layers above or below. Accordingly, conductive vias connect interconnect structures (e.g., conductive lines and/or conductive vias) of one metallization layer to interconnect structures of an adjacent metallization layer. While referred to as “metallization” layers, various layers of a metallization stack may include only certain patterns of conductive metals, e.g., copper (Cu), aluminum (Al), tungsten (W), or cobalt (Co), or metal alloys, or more generally, patterns of an electrically conductive material, formed in a medium of an insulator material such as an interlayer dielectric (ILD). The insulator medium may include any suitable ILD materials such as silicon oxide, carbon-doped silicon oxide, silicon carbide, silicon nitride, aluminum oxide, and/or silicon oxynitride.

In the past, the sizes and the spacing of conductive lines have progressively decreased, and it is expected that in the future the sizes and the spacing of interconnect structures will continue to progressively decrease, for at least some types of ICs (e.g., advanced microprocessors, chipset components, graphics chips, etc.). One measure of a size of a conductive line is line width. One measure of the spacing of conductive lines is line pitch, representing a center-to-center distance between the closest adjacent conductive lines of a given layer of a metallization stack.

Interconnect technology for semiconductor manufacturing demands smaller and smaller pitch for interconnect structures. Both trends increase capacitance and signal delay due to the close proximity of conductive lines to each other (e.g., due to the small pitch of the conductive lines). For example, in some IC designs with metallization stacks, a first conductive line in a first metallization layer in a metallization stack may be proximal to or aligned with a second conductive line in a second metallization layer in the metallization stack which is adjacent to the first metallization layer in the metallization stack, and proximity of the first and second conductive lines may increase capacitance and signal delay. In other IC designs with metallization stacks, a first conductive line in a first metallization layer in a metallization stack (e.g., arranged along a z-axis) may extend along a first direction (e.g., along an x-axis), a second conductive line in a second metallization layer in the metallization stack adjacent to the first metallization layer in the metallization stack may extend along a second direction orthogonal to the first direction (e.g., along a y-axis), and a third conductive line in a third metallization layer in the metallization stack adjacent to the second metallization layer in the metallization stack may extend along the first direction (e.g., along the x-axis). Similarly, proximity of the first conductive line and the third conductive line may increase capacitance and signal delay.

Current approaches to solving the challenge of increased capacitance include using dielectric materials having dielectric constants that are as low as possible in a metallization stack, as well as using airgap technology (where airgaps may be introduced to further decrease the dielectric constant of a material). However, additional approaches for further addressing the challenge of increased capacitance are desired.

Disclosed herein are IC structures and related semiconductor devices including metallization stacks having metallization layers with staggered conductive lines, as well as methods of fabricating such IC structures. An example IC structure may include a first metallization layer having a first conductive line, a second metallization layer having a second conductive line, and a third metallization layer having a third conductive line, where the first, second, and third metallization layers are stacked along a direction, and the second metallization layer is between the first and third metallization layers. The first and third conductive lines may have longitudinal axes along a first direction, and the second conductive line may have a longitudinal axis along a second direction substantially perpendicular to the first direction. The first conductive line and the third conductive line may be offset or staggered, meaning that a projection of the first conductive line onto a plane oriented perpendicular to the direction may be offset or staggered with respect to a projection of the third conductive line onto the plane. Staggering of the conductive lines (e.g., the first conductive line and the third conductive line) may allow for an increase in the distance between the conductive lines, thereby advantageously decreasing the capacitance between the conductive lines. Devices and methods described herein may provide improvements in terms of one or more of improved capacitance issues, reduced resistive-capacitive (RC) delays, and increased reliability.

IC structures as described herein, in particular metallization stacks having metallization layers with staggered conductive lines as described herein, may be used for providing electrical connectivity to one or more components associated with an IC or/and between various such components. In various embodiments, components associated with an IC include, for example, transistors, diodes, power sources, resistors, capacitors, inductors, sensors, transceivers, receivers, antennas, etc. Components associated with an IC may include those that are mounted on an IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

For purposes of explanation, specific numbers, materials, and configurations are set forth in order to provide a thorough understanding of the illustrative implementations. However, it will be apparent to one skilled in the art that the present disclosure may be practiced without the specific details and/or that the present disclosure may be practiced with only some of the described aspects. In other instances, well-known features are omitted or simplified in order not to obscure the illustrative implementations.

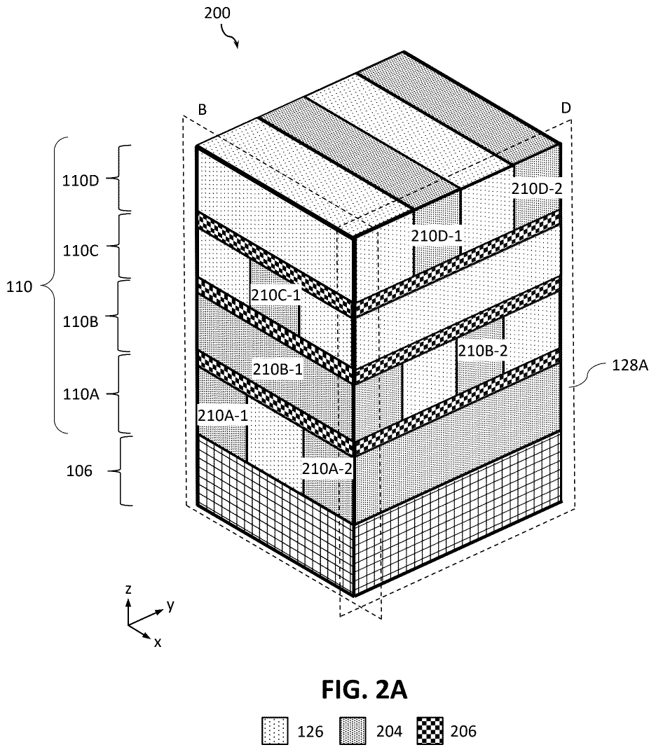

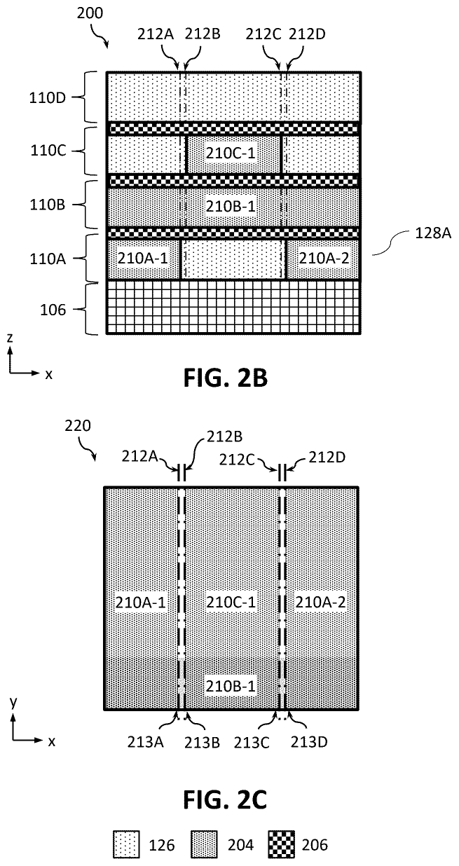

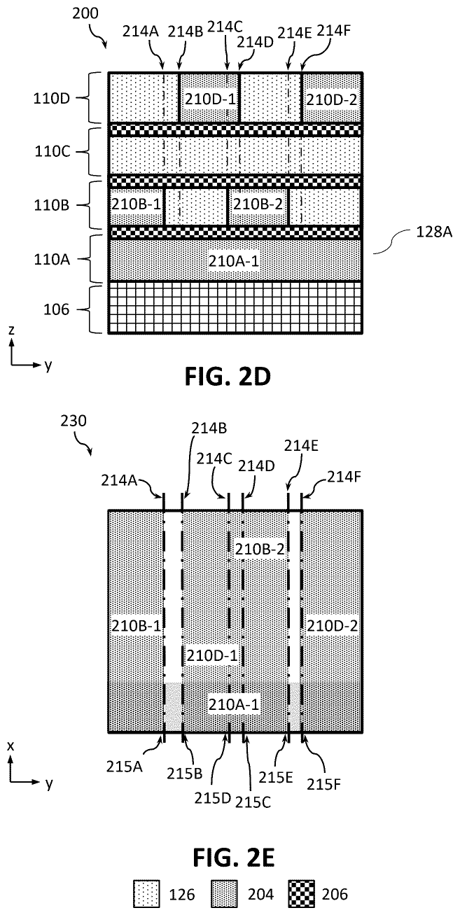

Further, references are made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense. For convenience, if a collection of drawings designated with different letters are present, e.g., FIGS. 2A-2E, such a collection may be referred to herein without the letters, e.g., as “FIG. 2.”

In the drawings, some schematic illustrations of example structures of various devices and assemblies described herein may be shown with precise right angles and straight lines, this is simply for ease of illustration, and embodiments of these assemblies may be curved, rounded, or otherwise irregularly shaped as dictated by, and sometimes inevitable due to, the manufacturing processes used to fabricate semiconductor device assemblies. Therefore, it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects or features could also be visible, e.g., not-perfectly straight edges of materials, tapered vias or other openings, rounding of corners or variations in thicknesses of different material layers, occasional screw, edge, or combination dislocations within crystalline regions of materials, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using e.g., Physical Failure Analysis (PFA) would allow determination of presence of one or more metallization stacks having metallization layers with staggered conductive lines as described herein.

Various operations may be described as multiple discrete actions or operations in turn, in a manner that is most helpful in understanding the claimed subject matter. However, the order of description should not be construed as to imply that these operations are necessarily order dependent. These operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges.

The description uses the phrases “in an embodiment” or “in embodiments,” which may each refer to one or more of the same or different embodiments. The terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, various aspects of the illustrative implementations will be described using terms commonly employed by those skilled in the art to convey the substance of their work to others skilled in the art. For example, if used, the terms “oxide,” “carbide,” “nitride,” etc. refer to compounds containing, respectively, oxygen, carbon, nitrogen, etc., the term “high-k dielectric” refers to a material having a higher dielectric constant than silicon oxide, and the term “low-k dielectric” refers to a material having a lower dielectric constant than silicon oxide. In another example, the term “insulating” and variations thereof (e.g., “insulative” or “insulator”) means “electrically insulating,” the term “conducting” and variations thereof (e.g., “conductive” or “conductor”) means “electrically conducting,” unless otherwise specified. Although certain elements may be referred to in the singular herein, such elements may include multiple sub-elements. For example, “an insulator material” may include one or more insulator materials. The terms “substantially,” “close,” “approximately,” “near,” and “about,” generally refer to being within +/−20% of a target value, e.g., within +/−10% of a target value or within +/−5% of a target value, based on the context of a particular value as described herein or as known in the art.

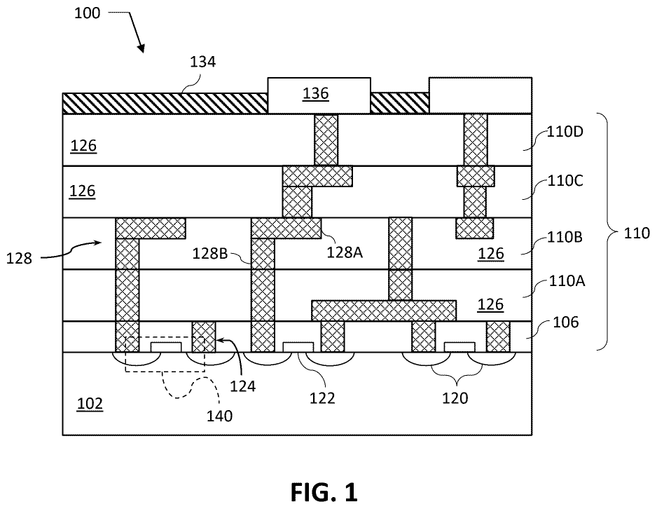

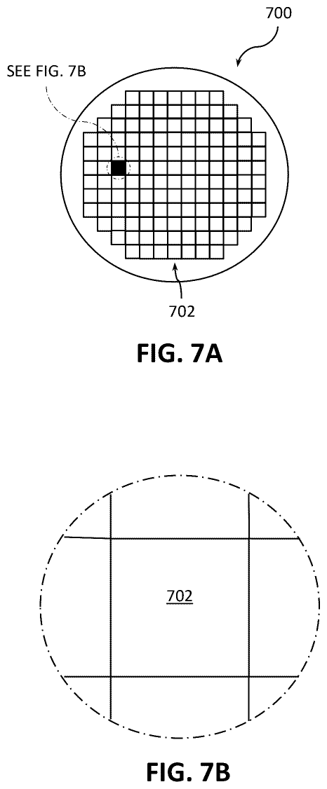

FIG. 1 is a cross-sectional side view of an IC device 100 that may include a metallization stack having metallization layers with staggered conductive lines, in accordance with various embodiments. The IC device 100 may be formed on a substrate 102 (e.g., the wafer 700 of FIG. 7A, as described further below) and may be included in a die (e.g., the die 702 of FIG. 7B, as described further below). The substrate 102 may be any substrate as described herein. The substrate 102 may be part of a singulated die (e.g., the dies 702 of FIG. 7B) or a wafer (e.g., the wafer 700 of FIG. 7A).

The IC device 100 may include one or more device layers 106 disposed on the substrate 102. The device layer 106 may include features of one or more transistors 140 (e.g., metal-oxide-semiconductor field effect transistors (MOSFETs)) formed on the substrate 102. The device layer 106 may include, for example, one or more source and/or drain (S/D) regions 120, a gate 122 to control current flow in the transistors 140 between the S/D regions 120, and one or more S/D contacts 124 to route electrical signals to/from the S/D regions 120. The transistors 140 may include additional features not depicted for the sake of clarity, such as device isolation regions, gate contacts, and the like. The transistors 140 are not limited to the type and configuration depicted in FIG. 1 and may include a wide variety of other types and configurations such as, for example, planar transistors, non-planar transistors, or a combination of both. Non-planar transistors may include fin-type field effect transistors (FinFETs), such as double-gate transistors or tri-gate transistors, and wrap-around or all-around gate transistors, such as nanoribbon and nanowire transistors.

Each transistor 140 may include a gate 122 formed of at least two layers, a gate electrode layer and a gate dielectric layer. The gate electrode layer may be formed on a gate interconnect support layer and may consist of at least one P-type workfunction metal or N-type workfunction metal, depending on whether the transistor is to be a P-type metal oxide semiconductor (PMOS) transistor or an N-type metal oxide semiconductor (NMOS) transistor, respectively. In some implementations, the gate electrode layer may consist of a stack of two or more metal layers, where one or more metal layers are workfunction metal layers and at least one metal layer is a fill metal layer. Further metal layers may be included for other purposes, such as a barrier layer or/and an adhesion layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer may enable the formation of a PMOS gate electrode with a workfunction that is between about 4.9 electron Volts (eV) and about 5.2 eV, for example. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, aluminum carbide, tungsten, tungsten carbide. An N-type metal layer may enable the formation of an NMOS gate electrode with a workfunction that is between about 3.9 eV and about 4.2 eV, for example.

In some embodiments, when viewed as a cross-section of the transistor 140 along the source-channel-drain direction, the gate electrode may be formed as a U-shaped structure that includes a bottom portion substantially parallel to the surface of the substrate and two sidewall portions that are substantially perpendicular to the top surface of the substrate. In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may be implemented as a combination of U-shaped structures and planar, non-U-shaped structures. For example, the gate electrode may be implemented as one or more U-shaped metal layers formed atop one or more planar, non-U-shaped layers. In some embodiments, the gate electrode may consist of a V-shaped structure (e.g., when a fin of a FinFET transistor does not have a “flat” upper surface, but instead has a rounded peak).

Generally, the gate dielectric layer of a transistor 140 may include one layer or a stack of layers, and the one or more layers may include silicon oxide, silicon dioxide, and/or a high-k dielectric material. The high-k dielectric material included in the gate dielectric layer of the transistor 140 may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The S/D regions 120 may be formed within the substrate 102 adjacent to the gate 122 of each transistor 140, using any suitable processes known in the art. For example, the S/D regions 120 may be formed using either an implantation/diffusion process or a deposition process. In the former process, dopants such as boron, aluminum, antimony, phosphorous, or arsenic may be ion-implanted into the substrate 102 to form the S/D regions 120. An annealing process that activates the dopants and causes them to diffuse farther into the substrate 102 may follow the ion implantation process. In the latter process, an epitaxial deposition process may provide material that is used to fabricate the S/D regions 120. In some implementations, the S/D regions 120 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 120 may be formed using one or more alternate semiconductor materials such as germanium or a group III-V material or alloy. In further embodiments, one or more layers of metal and/or metal alloys may be used to form the S/D regions 120. In some embodiments, an etch process may be performed before the epitaxial deposition to create recesses in the substrate 102 in which the material for the S/D regions 120 is deposited.

Electrical signals, such as power and/or input/output (I/O) signals, may be routed to and/or from the transistors 140 of the device layer 106 through one or more metallization layers disposed on the device layer 106 (illustrated in FIG. 1 as first, second, third, and fourth metallization layers 110A-110D, and further in FIG. 2 as described further below). For example, electrically conductive features of the device layer 106 (e.g., the gate 122 and the S/D contacts 124) may be electrically coupled with interconnect structures 128 of the metallization layers. The metallization layers may form a metallization stack 110 of the IC device 100.

The interconnect structures 128 may be arranged within the metallization layers to route electrical signals according to a wide variety of designs (in particular, the arrangement is not limited to the particular configuration of interconnect structures 128 depicted in FIG. 1). Although a particular number of metallization layers is depicted in FIG. 1 (i.e., four metallization layers 110A-110D), embodiments of the present disclosure may include IC devices having more or fewer metallization layers than depicted.

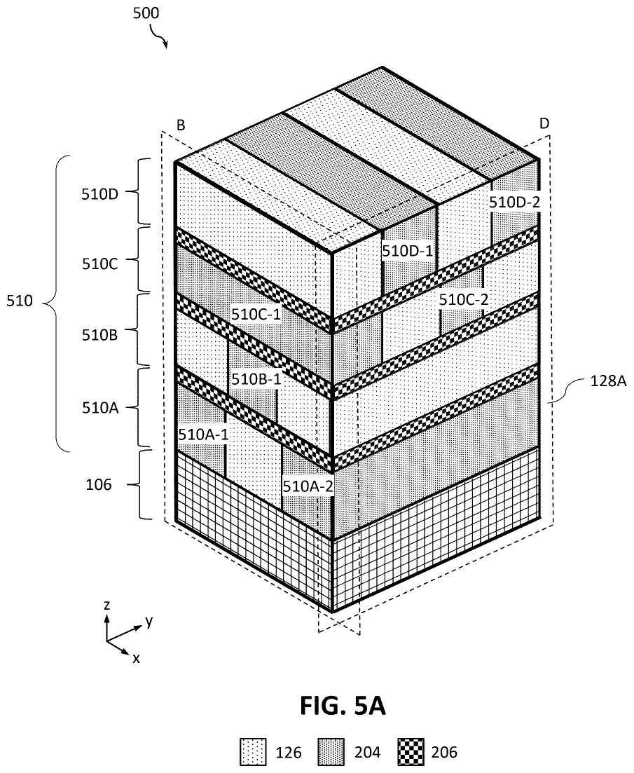

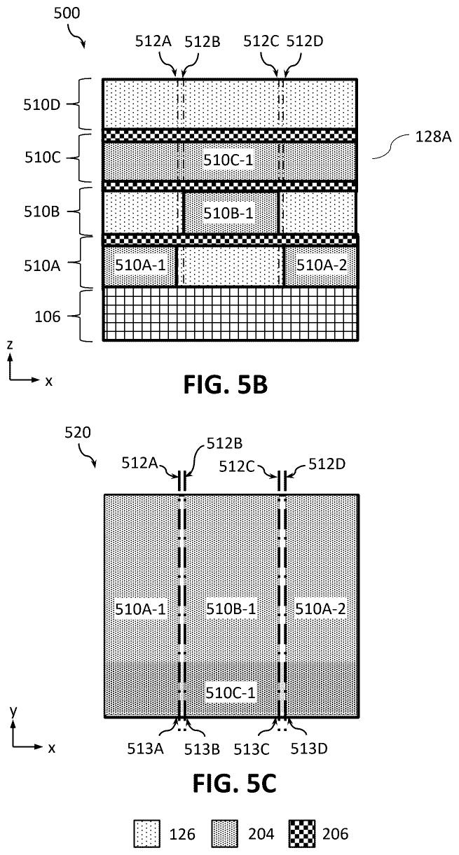

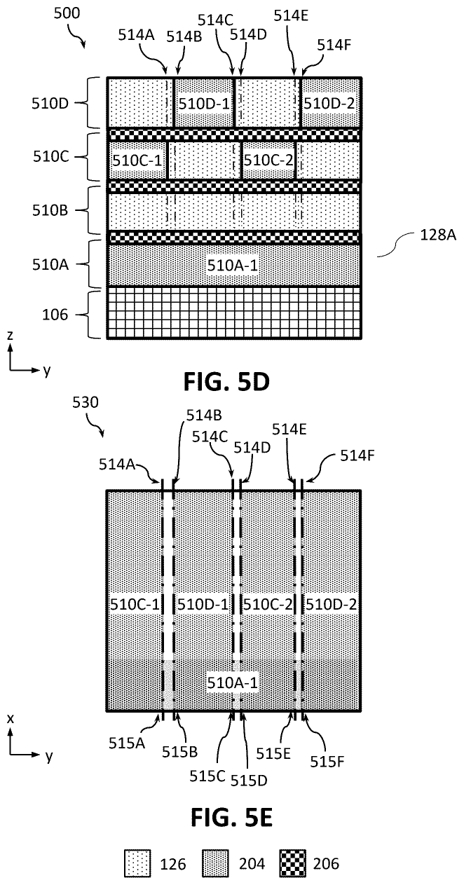

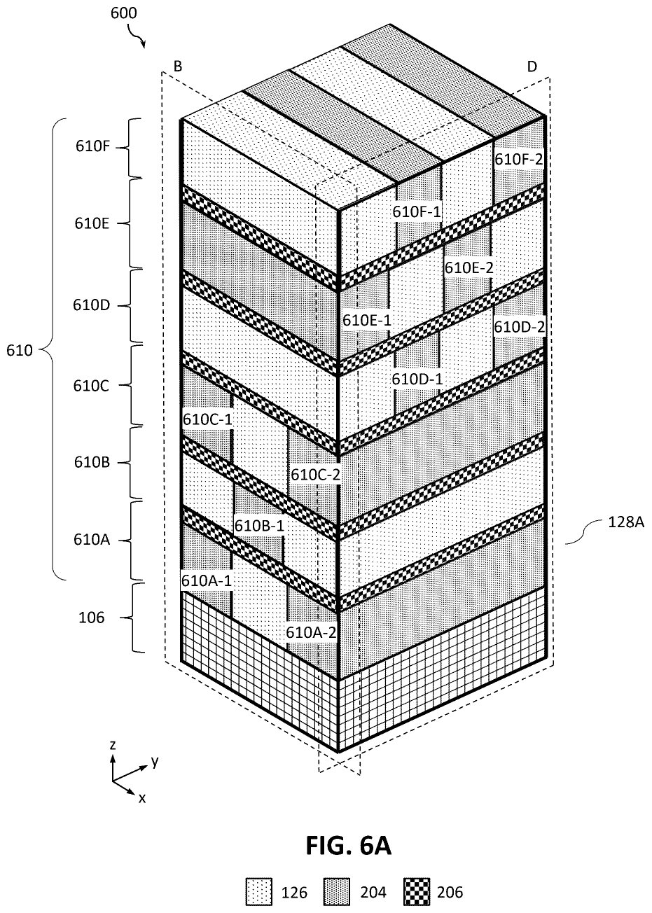

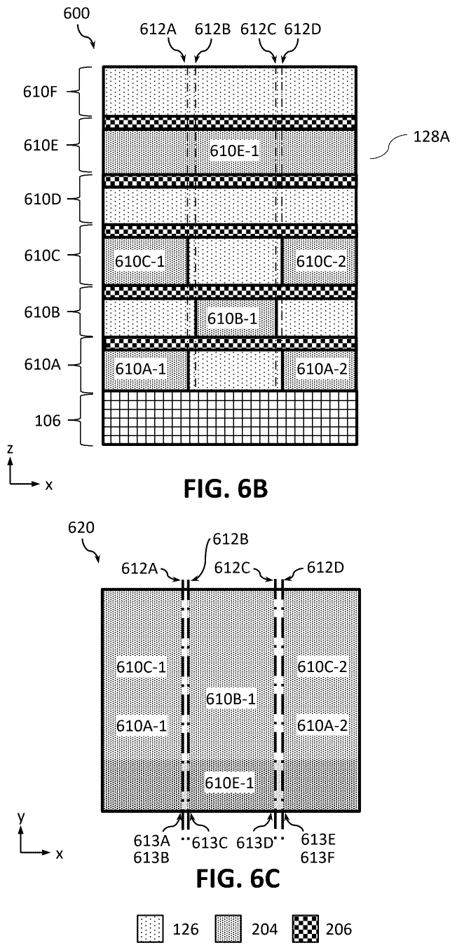

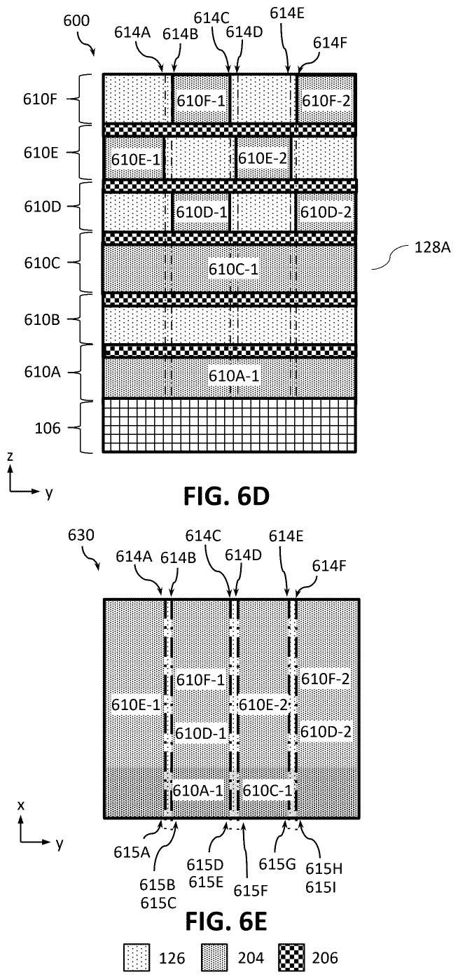

In some embodiments, the interconnect structures 128 may include conductive lines 128A and/or conductive vias 128B including an electrically conductive material including but not limited to a conductive metal (e.g., copper or another conductive metal). The conductive lines 128A may be arranged to route electrical signals in a direction of a plane that is substantially parallel with a surface of the substrate 102 upon which the device layer 106 is formed. For example, the conductive lines 128A may route electrical signals in a direction in and out of the page from the perspective of FIG. 1. The conductive vias 128B may be arranged to route electrical signals in a direction of a plane that is substantially perpendicular to the surface of the substrate 102 upon which the device layer 106 is formed. In some embodiments, the conductive vias 128B may electrically couple conductive lines 128A of metallization layers (e.g., metallization layers 110A-110D) together. Although it is not seen in the view of FIG. 1, in some embodiments, the conductive lines 128A of different metallization layers (e.g., of the metallization layers 110A-110D) may be arranged as staggered conductive lines, in accordance with various embodiments described herein. For example, each of an IC device 200 shown in FIG. 2, an IC device 500 shown in FIG. 5, and an IC device 600 shown in FIG. 6 is an example of the IC device 100 of FIG. 1, but showing metallization layers with staggered conductive lines.

The metallization layers may include a dielectric material 126 disposed between the interconnect structures 128, as shown in FIG. 1. The dielectric material 126 may take the form of any of the embodiments of the dielectric material provided between the interconnects of the IC structures disclosed herein. For example, the dielectric material 126 may include any suitable insulator material, such as one or more of silicon dioxide (SiO₂), carbon-doped oxide (CDO), silicon nitride, fluorosilicate glass (FSG), and organosilicates such as silsesquioxane, siloxane, or organosilicate glass. In some embodiments, the dielectric material 126 may include organic polymers such as polyimide, polynorbornenes, benzocyclobutene, perfluorocyclobutane, or polytetrafluoroethylene (PTFE). In some embodiments, the dielectric material 126 may include low-k dielectric materials such as silicon-based polymeric dielectrics (e.g., hydrogen silsesquioxane (HSQ) or methylsilsesquioxane (MSQ)).

In some embodiments, the dielectric material 126 disposed between the interconnect structures 128 in different ones of the metallization layers may have different compositions. In other embodiments, the composition of the dielectric material 126 between different metallization layers or between interconnect structures 128 may be the same.

As shown in the example embodiment of FIG. 1, a first metallization layer 110A may be formed directly on the device layer 106. In some embodiments, the first metallization layer 110A may include conductive lines 128A and/or conductive vias 128B, as shown. The conductive lines 128A of the first metallization layer 110A may be coupled with contacts (e.g., the S/D contacts 124) of the device layer 106.

A second metallization layer 110B may be formed over the first metallization layer 110A. In some embodiments, the second metallization layer 110B may include conductive vias 128B to couple the conductive lines 128A of the second metallization layer 110B with the conductive lines 128A of the first metallization layer 110A. Although the conductive lines 128A and the conductive vias 128B are structurally delineated with a line within each metallization layer (e.g., within the second metallization layer 110B) for the sake of clarity, the conductive lines 128A and the conductive vias 128B may be structurally and/or materially contiguous (e.g., simultaneously filled during a dual-damascene process) in some embodiments.

A third metallization layer 110C and a fourth metallization layer 110D (and additional metallization layers, as desired) may be formed in succession over the second metallization layer 110B according to similar techniques and configurations described in connection with the second metallization layer 110B or the first metallization layer 110A.

The IC device 100 may include a solder resist material 134 (e.g., polyimide or similar material) and one or more bond pads 136 formed on the metallization layers. The bond pads 136 may be electrically coupled with the interconnect structures 128 and configured to route the electrical signals of the transistor(s) 140 to other external devices. For example, solder bonds may be formed on the one or more bond pads 136 to mechanically and/or electrically couple a chip including the IC device 100 with another component (e.g., a circuit board). The IC device 100 may have other alternative configurations to route the electrical signals from the metallization layers than depicted in other embodiments. For example, the bond pads 136 may be replaced by or may further include other analogous features (e.g., posts) that route the electrical signals to external components.

FIG. 2A is an isometric view of an IC device 200 having a metallization stack 110 having metallization layers 110A-110D with staggered conductive lines, in accordance with some embodiments. The IC device 200 shown in FIG. 2A may be the same as or similar to the IC device 100 described above with reference to FIG. 1, or the IC device 200 may be a portion of the IC device 100. Parts of the IC device 200, such as the device layer 106, the first metallization layer 110A, the second metallization layer 110B, the conductive lines 128A, and so on, may be the same as described above with reference to the IC device 100 of FIG. 1. Some elements of the IC device 100 described above with reference to FIG. 1, such as the conductive vias 128B, may not be shown in the IC device 200 of FIG. 2A in order not to obscure the illustrative implementations; however, it should be understood that such elements may be included in the IC device 200.

A number of elements referred to in the descriptions of FIGS. 2A-2E with reference numerals are illustrated in these figures with different patterns, with a legend showing the correspondence between the reference numerals and patterns being provided at the bottom of each drawing page containing FIGS. 2A-2E. For example, the legend illustrates that FIGS. 2A-2E use different patterns to show a first dielectric material 126, an electrically conductive material 204, and a second dielectric material 206. Furthermore, although a certain number of a given element may be illustrated in some of FIGS. 2A-2E (e.g., two conductive lines 128A in the first metallization layer 110A, one conductive line 128A in the third metallization layer 110C, etc.), this is simply for ease of illustration, and more or less, than that number may be included in an IC structure according to various embodiments of the present disclosure. Still further, various IC structure views shown in FIGS. 2A-2E are intended to show relative arrangements of various elements therein, and various IC structures, or portions thereof, may include other elements or components that are not illustrated (e.g., transistor portions, various components that may be in electrical contact with any of the conductive lines 128A, etc.). In FIGS. 2A-2E, the conductive lines 128A are shown as elongated rectangular cuboids having longitudinal axes with rectangular cross-sections. However, in other embodiments, the conductive lines 128A may have other shapes, such as cylindrical (including elliptic cylindrical) shapes.

As shown in FIG. 2A and described above with reference to FIG. 1, the IC device 200 includes the device layer 106 and the metallization stack 110, which may include the first metallization layer 110A, the second metallization layer 110B, the third metallization layer 110C, and the fourth metallization layer 110D. The metallization layers 110A-110D in the metallization stack 110 may be stacked along a first direction or a stack direction (e.g., along the z-axis as shown in FIG. 2A) over the device layer 106 (e.g., such that the first metallization layer 110A is over the device layer 106, the second metallization layer 110B is over the first metallization layer 110A, the third metallization layer 110C is over the second metallization layer 110B, and the fourth metallization layer 110D is over the third metallization layer 110C). The second metallization layer 110B may be between the first metallization layer 110A and the third metallization layer 110C, and the third metallization layer 110C may be between the second metallization layer 110B and the fourth metallization layer 110D. The metallization layers 110A-110D may be separated by layers of dielectric material 206. The metallization layers 110A-110D may include conductive lines 128A and conductive vias 128B (the conductive vias 128B described above with reference to FIG. 1, but not shown in FIG. 2A).

As shown, the first metallization layer 110A may include first and second conductive lines 210A-1, 210A-2 which may be separated by or adjacent to masses of dielectric material 126. The first and second conductive lines 210A-1, 210A-2 may have longitudinal axes substantially along a second direction (e.g., along the y-axis in FIG. 2A) perpendicular to or orthogonal to the first direction (e.g., the z-axis in FIG. 2A). Stated in a different way, the first and second conductive lines 210A-1, 210A-2 may extend substantially along the second direction, or the first and second conductive lines 210A-1, 210A-2 may be substantially elongated in the second direction. The first and second conductive lines 210A-1, 210A-2 may be substantially parallel to one another.

The second metallization layer 110B may include third and fourth conductive lines 210B-1, 210B-2 which may be separated by or adjacent to masses of dielectric material 126. The third and fourth conductive lines 210B-1, 210B-2 may have longitudinal axes along a third direction (e.g., along the x-axis in FIG. 2A) substantially perpendicular to or orthogonal to the first direction (e.g., the z-axis in FIG. 2A) and the second direction (e.g., the y-axis in FIG. 2A). The third and fourth conductive lines 210B-1, 210B-2 may be substantially parallel to one another.

The third metallization layer 110C may include a fifth conductive line 210C-1, which may be adjacent to masses of dielectric material 126. The fifth conductive line 210C-1 may have a longitudinal axis along the second direction (e.g., along the y-axis in FIG. 2A), or along a fourth direction substantially parallel to the second direction.

The fourth metallization layer 110D may include sixth and seventh conductive lines 210D-1, 210D-2, which may be separated by or adjacent to masses of dielectric material 126. The sixth and seventh conductive lines 210D-1, 210D-2 may have longitudinal axes along the third direction (e.g., along the x-axis in FIG. 2A), or along a fifth direction substantially parallel to the third direction. The sixth and seventh conductive lines 210D-1, 210D-2 may be substantially parallel to one another.

FIG. 2B is a cross-sectional view of the IC device shown in FIG. 2A along plane B (e.g., along the z and x-axes). The first, second, third, and fifth conductive lines 210A-1, 210A-2, 210B-1, 210C-1 are visible in FIG. 2B, and other conductive lines 128A are not visible in the view of plane B. Projection planes 212A, 212B, 212C, 212D (e.g., imaginary planes) along the z and y-axes (y-axis not shown in FIG. 2B, but shown in FIG. 2C as described further below) include sides of the conductive lines 210A-1, 210A-2, 210B-1, 210C-1. In particular, projection plane 212A includes a first side 213A (as indicated in FIG. 2C) of the first conductive line 210A-1, projection planes 212B and 212C include first and second sides 213B, 213C of the fifth conductive line 210C-1, and projection plane 212D includes a first side 213D of the second conductive line 210A-1.

As shown in FIG. 2B, the projection planes 212A-212D are substantially parallel to the stack direction (e.g., along the z-axis) and substantially perpendicular to the longitudinal axes of the first, second, third, and fifth conductive lines 210A-1, 210A-2, 210B-1, 210C-1 (e.g., along the x- and y-axes). At least one projection plane (e.g., projection plane 212A) includes a portion of the first conductive line 210A-1, and does not include any portion of the fifth conductive line 210C-1, and at least one projection plane (e.g., projection plane 212B) includes a portion of the fifth conductive line 210C-1, and does not include any portion of the first conductive line 210A-1. In FIG. 2B, no projection plane substantially parallel to the stack direction (e.g., along the z-axis) and substantially perpendicular to the longitudinal axes of the first, second, third, and fifth conductive lines 210A-1, 210A-2, 210B-1, 210C-1 (e.g., along the x- and y-axes) includes both a portion of the first conductive line 210A-1 and a portion of the fifth conductive line 210C-1.

FIG. 2C is a view of a plane 220 (e.g., an imaginary plane along the y and x-axes, perpendicular to the first direction (e.g., along the z-axis)), and projections of the first, second, third, and fifth conductive lines 210A-1, 210A-2, 210B-1, and 210C-1 are shown on the plane 220. The projection planes 212A, 212B, 212C, 212D along the z- and y-axes (z-axis not shown in FIG. 2C, but shown in FIG. 2B) are shown at sides of the projections of the first, second, and fifth conductive lines 210A-1, 210A-2, and 210C-1 onto the plane 220. As shown, the projections of the first, second, and fifth conductive lines 210A-1, 210A-2, and 210C-1 onto the plane 220 are staggered or offset relative to one another. In particular, the projection of the first conductive line 210A-1 onto the plane 220 is offset with respect to the projection of the fifth conductive line 210C-1 onto the plane 220, and the projection of the fifth conductive line 210C-1 onto the plane 220 is offset with respect to the projection of the second conductive line 210A-2 onto the plane 220. The projection of the first conductive line 210A-1 onto the plane 220 does not overlap with the projection of the fifth conductive line 210C-1 onto the plane 220, and the projection of the fifth conductive line 210C-1 onto the plane 220 does not overlap with the projection of the second conductive line 210A-2 onto the plane 220. The projection of the third conductive line 210B-1 onto the plane 220 intersects the projection of the first, second, and fifth conductive lines 210A-1, 210A-2, 210C-1 onto the plane 220.

Stated in another way, the plane 220 may be considered a superposed plane, the superposed plane including a superposition of a first superposition plane including a portion of the first conductive line 210A-1, a second superposition plane including a portion of the second conductive line 210A-2, a third superposition plane including a portion of the third conductive line 210B-1, and a fourth superposition plane including a portion of the fifth conductive line 210C-1, the first, second, third, and fourth superposition planes oriented substantially perpendicular to the stack direction (e.g., the first, second, third, and fourth superposition planes being oriented along the x-y axes perpendicular to the z-axis). In the superposed plane, the portion of the first conductive line 210A-1 and the portion of the fifth conductive line 210C-1 are separated, and occupy a larger portion of the superposed plane than either the portion of the first conductive line 210A-1 or the portion of the fifth conductive line 210C-1 individually. Furthermore, in the superposed plane, the portion of the second conductive line 210A-2 and the portion of the fifth conductive line 210C-1 are separated, and occupy a larger portion of the superposed plane than either the portion of the second conductive line 210A-2 or the portion of the fifth conductive line 210C-1 individually. In the superposed plane, the portion of the third conductive line 210B-1 is joined with the portion of the first conductive line 210A-1, the portion of the second conductive line 210A-2, and the portion of the fifth conductive line 210C-1.

FIG. 2D is a cross-sectional view of the IC device shown in FIG. 2A along plane D (e.g., along the z and y-axes). The first, third, fourth, sixth, and seventh conductive lines 210A-1, 210B-1, 210B-2, 210D-1, 210D-2 are visible in FIG. 2D, and other conductive lines 128A are not visible in the view of plane D. Projection planes 214A, 214B, 214C, 214D, 214E, 214F (e.g., imaginary planes) along the z and x-axes (x-axis not shown in FIG. 2D, but shown in FIG. 2E as described further below) include sides of the third, fourth, sixth, and seventh conductive lines 210B-1, 210B-2, 210D-1, 210D-2. In particular, projection plane 214A includes a first side 215A of the third conductive line 210B-1 (as shown in FIG. 2E), projection planes 214B and 214D include first and second sides 215B, 215C of the sixth conductive line 210D-1, projection planes 214C and 214E include first and second sides 215D, 215E of the fourth conductive line 210B-2, and projection plane 214F includes a first side 215F of the seventh conductive line 210D-2.

As shown in FIG. 2D, the projection planes 214A-214F are substantially parallel to the stack direction (e.g., along the z-axis) and substantially perpendicular to the longitudinal axes of the first, third, fourth, sixth, and seventh conductive lines 210A-1, 210B-1, 210B-2, 210D-1, 210D-2 (e.g., along the x- and y-axes). At least one projection plane (e.g., projection plane 214A) includes a portion of the third conductive line 210B-1, and does not include any portion of the sixth conductive line 210D-1, and at least one projection plane (e.g., projection plane 214B) includes a portion of the sixth conductive line 210D-1, and does not include any portion of the third conductive line 210B-1. In FIG. 2D, no projection plane substantially parallel to the stack direction (e.g., along the z-axis) and substantially perpendicular to the longitudinal axes of the first, third, fourth, sixth, and seventh fifth conductive lines 210A-1, 210B-1, 210B-2, 210D-1, 210D-2 (e.g., along the x- and y-axes) includes both a portion of the third conductive line 210B-1 and a portion of the sixth conductive line 210D-1.

As shown in FIG. 2D, at least one projection plane (e.g., projection plane 214B) includes a portion of the sixth conductive line 210D-1, and does not include any portion of the fourth conductive line 210B-2, and at least one projection plane (e.g., projection plane 214E) includes a portion of the fourth conductive line 210B-2, and does not include any portion of the sixth conductive line 210D-1. Additionally, at least one projection plane substantially parallel to the stack direction (e.g., along the z-axis) and substantially perpendicular to the longitudinal axes of the first, third, fourth, sixth, and seventh conductive lines 210A-1, 210B-1, 210B-2, 210D-1, 210D-2 includes both a portion of the fourth conductive line 210B-2 and a portion of the sixth conductive line 210D-1 (e.g., the projection planes 214C and 214D).

FIG. 2E is a view of a plane 230 (e.g., an imaginary plane along the x and y-axes, perpendicular to the first direction (e.g., along the z-axis)), and projections of the first, third, fourth, sixth, and seventh conductive lines 210A-1, 210B-1, 210B-2, 210D-1, and 210D-2 are shown on the plane 230. The projection planes 214A, 214B, 214C, 214D, 214E, 214F along the z- and x-axes (z-axis not shown in FIG. 2E, but shown in FIG. 2D) are shown at sides of the projections of the third, fourth, sixth, and seventh conductive lines 210B-1, 210B-2, 210D-1, 210D-2 onto the plane 230. As shown, the projections of the third, fourth, sixth, and seventh conductive lines 210B-1, 210B-2, 210D-1, 210D-2 onto the plane 230 are staggered or offset relative to one another. In particular, the projection of the third conductive line 210B-1 onto the plane 230 is offset with respect to the projection of the sixth conductive line 210D-1 onto the plane 230, the projection of the sixth conductive line 210D-1 onto the plane 230 is offset with respect to the projection of the fourth conductive line 210B-2 onto the plane 230, and the projection of the fourth conductive line 210B-2 is offset with respect to the projection of the seventh conductive line 210D-2 onto the plane 230. The projection of the third conductive line 210B-1 onto the plane 230 does not overlap with the projection of the sixth conductive line 210D-1 onto the plane 230, and the projection of the fourth conductive line 210B-2 onto the plane 230 does not overlap with the projection of the seventh conductive line 210D-2 onto the plane 230. As shown in FIG. 2E, the projection of the sixth conductive line 210D-1 onto the plane 230 partially overlaps with the projection of the fourth conductive line 210B-2 onto the plane 230. The projection of the first conductive line 210A-1 onto the plane 230 intersects the projections of the third, fourth, sixth, and seventh conductive lines 210B-1, 210B-2, 210D-1, 210D-2 onto the plane 230.

Similarly to the plane 220 of FIG. 2C, the plane 230 of FIG. 2E may be considered a superposed plane, the superposed plane including a superposition of a first superposition plane including a portion of the first conductive line 210A-1, a second superposition plane including a portion of the third conductive line 210B-1, a third superposition plane including a portion of the fourth conductive line 210B-2, a fourth superposition plane including a portion of the sixth conductive line 210D-1, and a fifth superposition plane including a portion of the seventh conductive line 210D-2, the first, second, third, fourth, and fifth superposition planes oriented substantially perpendicular to the stack direction (e.g., the first, second, third, fourth, and fifth superposition planes being oriented along the x-y axes, perpendicular to the z-axis). In the superposed plane, the portion of the third conductive line 210B-1 and the portion of the sixth conductive line 210D-1 are separated, and occupy a larger portion of the superposed plane than either the portion of the third conductive line 210B-1 or the portion of the sixth conductive line 210D-1 individually. Additionally, in the superposed plane, the portion of the fourth conductive line 210B-2 and the portion of the seventh conductive line 210D-2 are separated, and occupy a larger portion of the superposed plane than either the portion of the fourth conductive line 210B-2 or the portion of the seventh conductive line 210D-2 individually. Furthermore, in the superposed plane, the portion of the fourth conductive line 210B-2 and the portion of the sixth conductive line 210D-1 are joined, and occupy a larger portion of the superposed plane than either the portion of the fourth conductive line 210B-2 or the portion of the sixth conductive line 210D-1 individually. In the superposed plane, the portion of the first conductive line 210A-1 is joined with the portions of the third, fourth, sixth, and seventh conductive lines 210B-1, 210B-2, 210D-1, 210D-2.

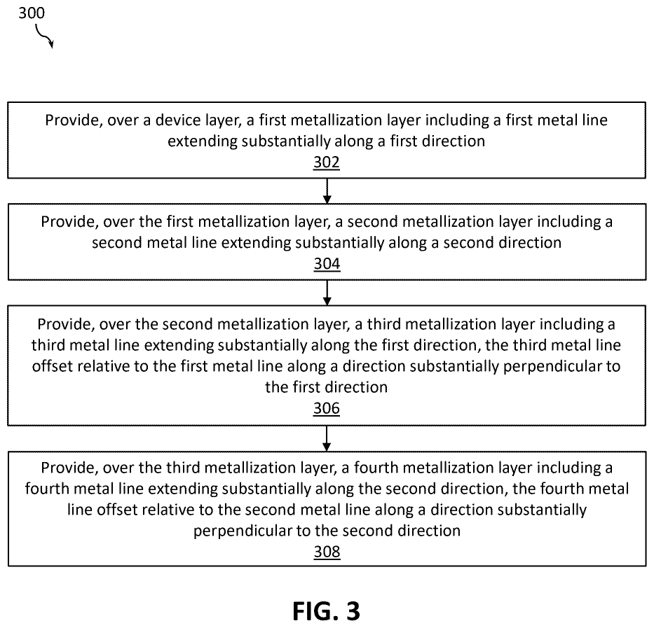

FIG. 3 is a flow diagram of an example method 300 for providing a metallization stack (e.g., as part of an IC device or structure) having metallization layers with staggered conductive lines, e.g., the metallization stack 110 of the IC device 200 shown in FIG. 2A, in accordance with some embodiments.

Although the operations of the method 300 are illustrated once each and in a particular order, the operations may be performed in any suitable order and repeated as desired. For example, one or more operations may be performed in parallel to manufacture, substantially simultaneously, multiple staggered conductive lines in multiple metallization layers (e.g., in one metallization stack or in multiple metallization stacks as described herein). In another example, the operations may be performed in a different order to reflect the structure of an IC device or structure in which one or more metallization stacks having metallization layers with staggered conductive lines as described herein will be included.

In addition, the example manufacturing method 300 may include other operations not specifically shown in or described with reference to FIG. 3, such as various cleaning or planarization operations as known in the art. For example, in some embodiments, a device layer, as well as layers of various other materials subsequently deposited thereon, may be cleaned prior to, after, or during any of the processes of the method 300 described herein, e.g., to remove oxides, surface-bound organic and metallic contaminants, as well as subsurface contamination. In some embodiments, cleaning may be carried out using e.g., a chemical solutions (such as peroxide), and/or with ultraviolet (UV) radiation combined with ozone, and/or oxidizing the surface (e.g., using thermal oxidation) then removing the oxide (e.g., using hydrofluoric acid (HF)). In another example, the arrangements/devices described herein may be planarized prior to, after, or during any of the processes of the method 300 described herein, e.g., to remove overburden or excess materials. In some embodiments, planarization may be carried out using either wet or dry planarization processes, e.g., chemical mechanical planarization (CMP), which may be understood as a process that utilizes a polishing surface, an abrasive and a slurry to remove the overburden and planarize the surface.

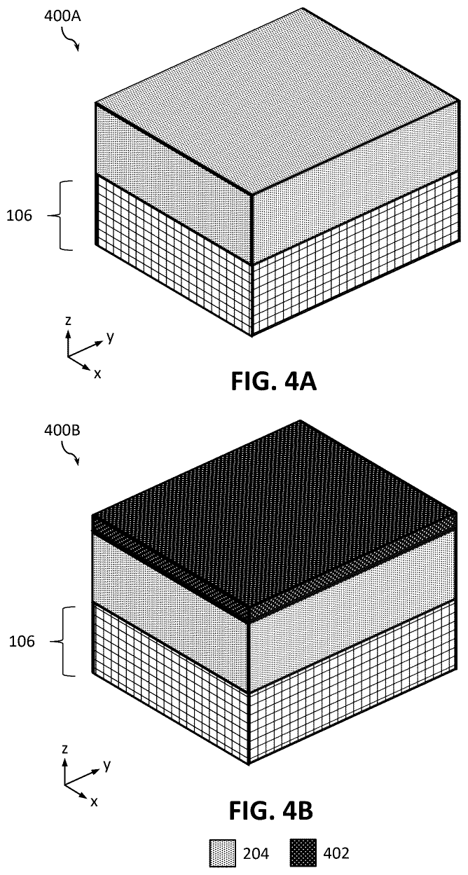

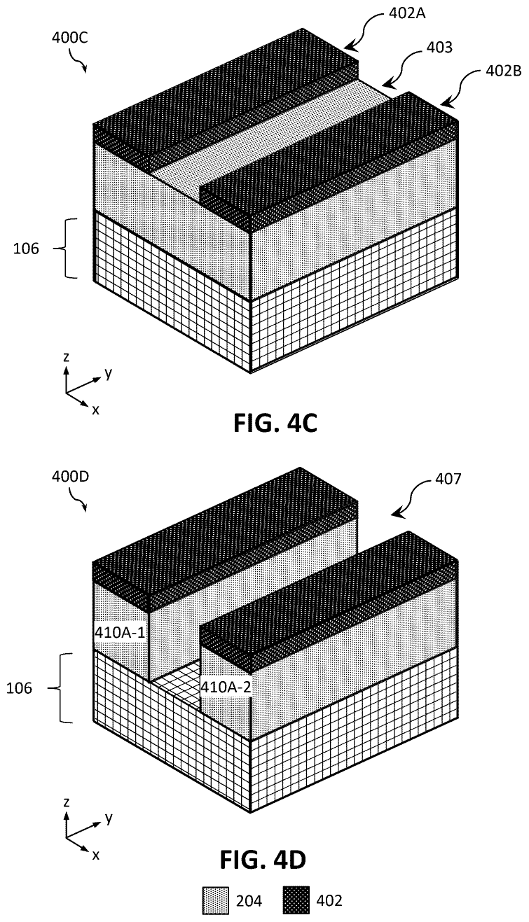

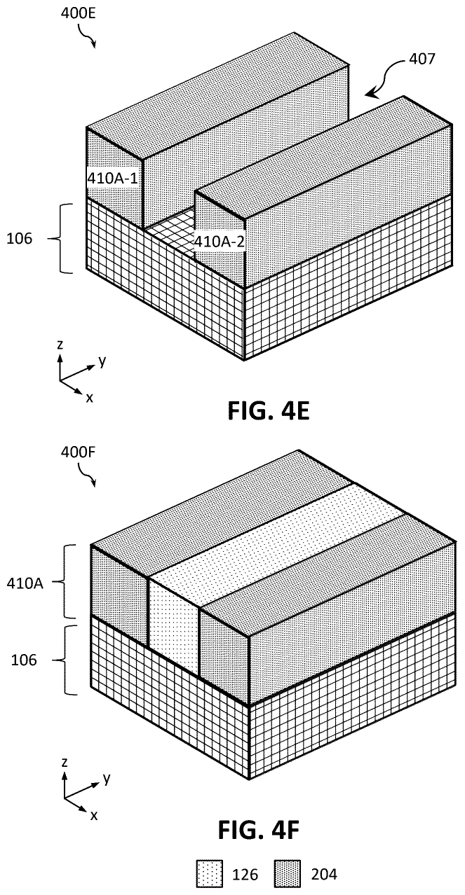

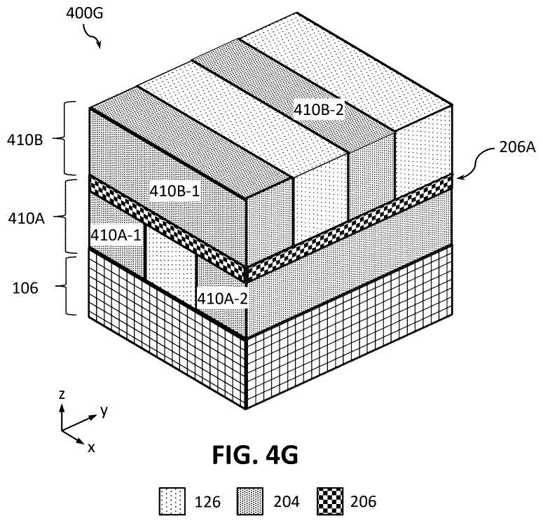

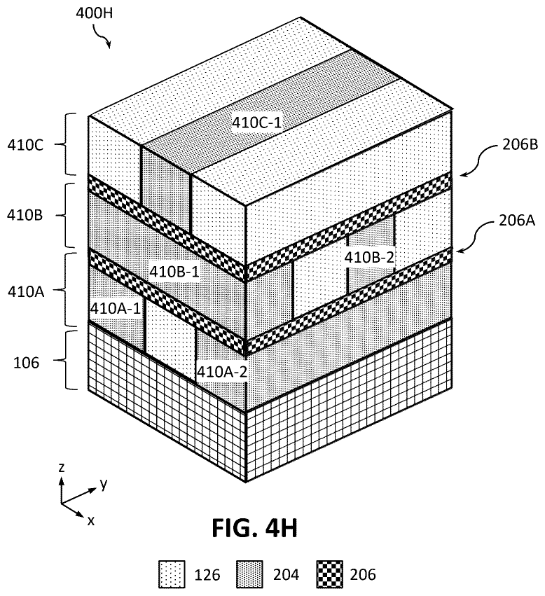

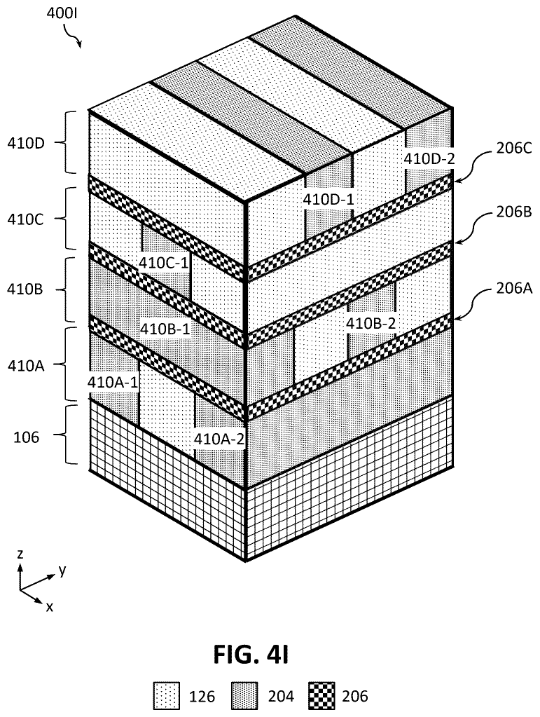

Various operations of the method 300 may be illustrated with reference to the example embodiments shown in FIGS. 4A-4I, illustrating isometric views for various stages in the manufacture of an example IC structure that includes a metallization stack having metallization layers with staggered conductive lines according to the method 300, and in accordance with some embodiments. For example, results of different processes of the method 300 are illustrated as IC structures 400A-400F shown in FIG. 4A-4F as an example result of a process 302 of the method 300, as an IC structure 400G shown in FIG. 4G as an example result of a process 304 of the method 300, as an IC structure 400H shown in FIG. 4H as an example result of a process 306 of the method 300, and as an IC structure 400I shown in FIG. 4I as an example result of a process 308 of the method 300. Similarly to FIG. 2A-2E and the accompanying text above, a number of elements referred to in the description of FIGS. 4A-4I with reference numerals are illustrated in these figures with different patterns, with a legend showing the correspondence between the reference numerals and patterns being provided at the bottom of each drawing page containing FIGS. 4A-4I.

Referring to FIG. 3, in process 302, a first metallization layer including a first conductive line extending substantially along a first direction may be provided over a device layer. The IC structure 400F, depicted in FIG. 4F, illustrates an example result of process 302, and the IC structures 400A-400E, depicted in FIGS. 4A-4E, illustrate intermediate results of process 302.

FIG. 4A shows the IC structure 400A, which includes a layer of a conductive material 204 over a device layer 106. The layer of conductive material 204 may be formed over the device layer 106 using a deposition technique such as, but not limited to, atomic layer deposition (ALD), chemical vapor deposition (CVD), plasma enhanced CVD (PECVD), physical vapor deposition (PVD) (e.g., evaporative deposition, magnetron sputtering, or e-beam deposition), or electroplating. In general, the conductive material 204 may include one or more of any suitable electrically conductive materials or conductors. Such materials may include any suitable electrically conductive material, alloy, or a stack of multiple electrically conductive materials. In some embodiments, various electrically conductive materials described herein may include one or more metals or metal alloys, with metals such as copper, ruthenium, palladium, platinum, cobalt, nickel, hafnium, zirconium, titanium, tantalum, and aluminum. In some embodiments, various electrically conductive materials described herein may include one or more electrically conductive alloys, oxides (e.g., conductive metal oxides), carbides (e.g., hafnium carbide, zirconium carbide, titanium carbide, tantalum carbide, and aluminum carbide, tungsten, tungsten carbide), or nitrides (e.g. hafnium nitride, zirconium nitride, titanium nitride, tantalum nitride, and aluminum nitride) of one or more metals.

FIG. 4B shows the IC structure 400B, which may be the same as the IC structure 400A, but further including a layer of a resist material 402 (e.g., a photoresist material) over the layer of conductive material 204. In various embodiments, the resist material 402 may be provided using any suitable deposition technique such as, but not limited to, spin-coating, dip-coating, CVD, etc. Various materials that may be used as the resist material 402 are well-known in the art and, therefore, in the interests of brevity are not described herein detail.

FIG. 4C shows the IC structure 400C, which may be the same as the IC structure 400B, but after a process of removing a portion of the resist material 402 (e.g., patterning the layer of the resist material 402) to define locations and dimensions of future conductive lines (or, more generally, conductive lines) in the conductive material 204. The resist material 402 may be patterned using a technique known in the art, such as photolithographic patterning, to take shape of a plurality of resist lines (shown in FIG. 4C as two resist lines 402A, 402B). An opening 403 (e.g., gap) may be formed between the resist lines 402A, 402B so that a portion of the conductive material 204 is exposed in the opening 403.

FIG. 4D shows the IC structure 400D, which may be the same as the IC structure 400C, but after a process of removing a portion of the conductive material 204 through the opening 403. The conductive material 204 may be removed by any suitable technique known in the art, such as by an etching process. As shown in FIG. 4D, the conductive material 204 that has been exposed through the opening 403 is removed, so that the remainder of the conductive material 204 takes shape of conductive lines 410A-1, 410A-2 that extend along the first direction (e.g., along the y-axis as shown in FIG. 4D). Any suitable etching technique, e.g., a dry etch, such as e.g., radio frequency (RF) reactive ion etch (RIE) or inductively coupled plasma (ICP) RIE, may be used in the etching process. In some embodiments, the etch performed in the process may include an anisotropic etch, using etchants in a form of e.g., chemically active ionized gas (i.e., plasma) using e.g., bromine (Br) and chloride (CI) based chemistries. In some embodiments, during the etching process, the IC structure may be heated to elevated temperatures, e.g., to temperatures between about room temperature and 200 degrees Celsius, including all values and ranges therein, to promote that byproducts of the etch are made sufficiently volatile to be removed from the surface. An opening 407 is formed between the conductive lines 410A-1, 410A-2 so that the device layer 106 is exposed in the opening 407.

FIG. 4E shows the IC structure 400E, which may be the same as the IC structure 400D, but after a process of removing the remaining portion of the resist material 402 shown in FIG. 4D. The remainder of the resist material 402 may be removed by any suitable process. For example, in some embodiments, the remaining resist material 402 may be removed using an ashing technique, where the resist material 402 is exposed to oxygen or fluorine, which combines with the resist material 402 to form ash that can be easily removed. The process of removal of the resist material 402 exposes the conductive lines 410A-1, 410A-2.

FIG. 4F shows the IC structure 400F, which may be the same as the IC structure 400E, but after a process of providing a dielectric material 126 in the opening 407 (shown in FIG. 4D). Any suitable process may be used to provide the dielectric material 126. For example, the process of providing the dielectric material 126 may include a conformal deposition process (such as ALD or CVD) over the portion of the device layer 106 exposed through the opening 407 and/or over the conductive lines 410A-1, 410A-2. The process of providing the dielectric material 126 in the opening 407 may complete the formation of a first metallization layer 410A over the device layer 106. However, in some embodiments, additional processes or fewer processes may be used to complete the formation of the first metallization layer 410A.

Referring back to FIG. 3, in process 304, a second metallization layer including a second conductive line extending substantially along a second direction may be provided over the first metallization layer. The IC structure 400G, depicted in FIG. 4G, illustrates an example result of process 304.

FIG. 4G shows the IC structure 400G, which may be the same as the IC structure 400F, but after the process 304 of providing a second metallization layer 410B over the first metallization layer 410A. The process 304 may involve a process of providing a layer of insulation 206A (e.g., including a dielectric material 206) over the first metallization layer 410A in order to at least partially electrically isolate the conductive lines 410A-1, 410A-2 of the first metallization layer 410A and conductive lines 410B-1, 410B-2 of the second metallization layer. The conductive lines 410B-1, 410B-2 may extend along the second direction (e.g., along a second direction substantially perpendicular to the first direction, such as along the x-axis, as shown in FIG. 4G). The dielectric material 206 may be the same as or similar to the dielectric material 126, or the dielectric material 206 may be a different dielectric material. The dielectric material 206 may be provided over the first metallization layer 410A by a deposition process which may be the same as or similar to the deposition process used to deposit the dielectric material 126 (e.g., ALD or CVD), or by a different process. Openings may be made in the dielectric material 206 as suitable to allow for electrical communication between the first metallization layer 410A and the second metallization layer 410B (e.g., by conductive vias coupled to one or more of the conductive lines, not shown). The process 304 may involve processes for providing the second metallization layer 410B over the first metallization layer 410A (e.g., over the layer of insulation 206A) which may be the same as or similar to processes for forming the first metallization layer 410A over the device layer 106 as described above (e.g., involving processes of forming a layer of conductive material 204 over the layer of insulation 206A using a deposition technique, providing a layer of a resist material 402, etc.).

Referring back to FIG. 3, in process 306, a third metallization layer including a third conductive line extending substantially along the first direction is provided over the second metallization layer, where the third conductive line is offset relative to the first conductive line along a direction substantially perpendicular to the first direction (e.g., along the second direction). The IC structure 400H, depicted in FIG. 4H, illustrates an example result of process 306.

FIG. 4H shows the IC structure 400H, which may be the same as the IC structure 400G, but after the process 306 of providing a third metallization layer 410C over the second metallization layer 410B. The process 306 may be similar to the process 304, and may involve similar techniques (e.g., providing a layer of insulation 206B (e.g., including dielectric material 206) over the second metallization layer 410B, providing a layer of conductive material 204 over the second metallization layer 410B (or over the layer of insulation 206B), etc.). A conductive line 410C-1 formed in the third metallization layer 410C (e.g., the third conductive line) may extend substantially along the first direction (e.g., along the y-axis, and substantially perpendicular to the second direction (e.g., along the x-axis)). The conductive line 410C-1 is staggered or offset relative to the conductive lines 410A-1, 410A-2 along a direction substantially perpendicular to the first direction (e.g., along the x-axis) as described above with reference to the IC device 200 of FIG. 2.

FIG. 4I shows the IC structure 400I, which may be the same as the IC structure 400H, but after the process 308 of providing a fourth metallization layer 410D over the third metallization layer 410C. The process 308 may be similar to the process 306, and may involve similar techniques (e.g., providing a layer of insulation 206C (e.g., including dielectric material 206) over the third metallization layer 410C, providing a layer of conductive material 204 over the third metallization layer 410C (or over the layer of insulation 206C), etc.). Conductive lines 410D-1, 410D-2 in the fourth metallization layer 410D (e.g., the fourth conductive lines) may extend substantially along the second direction (e.g., along the x-axis, and substantially perpendicular to the first direction (e.g., along the y-axis)). The conductive lines 410D-1, 410D-2 are offset relative to the conductive lines 410B-1, 410B-2 along a direction substantially perpendicular to the second direction (e.g., along the y-axis) as described further above with reference to FIGS. 2A-2E.

FIG. 5A is an isometric view of an alternative IC device 500 including a metallization stack having metallization layers with staggered conductive lines, in accordance with some embodiments. Parts of the alternative IC device 500, such as device layer 106, dielectric materials 126, 206, conductive material 204, and so on, may be the same as presented in FIG. 2A, and are not described further here in detail.

As shown in FIG. 5A, the IC device 500 includes the device layer 106 and the metallization stack 510, which may include the first metallization layer 510A, the second metallization layer 510B, the third metallization layer 510C, and the fourth metallization layer 510D. The metallization layers 510A-510D in the metallization stack 510 may be stacked along a first direction or a stack direction (e.g., along the z-axis as shown in FIG. 5A) over the device layer 106 (e.g., such that the first metallization layer 510A is over the device layer 106, the second metallization layer 510B is over the first metallization layer 510A, the third metallization layer 510C is over the second metallization layer 510B, and the fourth metallization layer 510D is over the third metallization layer 510C). The second metallization layer 510B may be between the first metallization layer 510A and the third metallization layer 510C, and the third metallization layer 510C may be between the second metallization layer 510B and the fourth metallization layer 510D. The metallization layers 510A-510D may be separated by layers of dielectric material 206, and may include conductive lines 128A and conductive vias 128B (the conductive vias 128B described above with reference to FIG. 1, but not shown in FIG. 5A). The conductive lines 128A may include the conductive material 204.

As shown, the first metallization layer 510A may include first and second conductive lines 510A-1 and 510A-2, which may be separated by or adjacent to masses of dielectric material 126. The first and second conductive lines 510A-1, 510A-2 may have longitudinal axes substantially along a second direction (e.g., along the y-axis in FIG. 2A) perpendicular to or orthogonal to the first direction (e.g., the z-axis in FIG. 2A). Stated in a different way, the first and second conductive lines 510A-1, 510A-2 may extend substantially along the second direction, or the first and second conductive lines 510A-1, 510A-2 may be substantially elongated in the second direction. The first and second conductive lines 510A-1, 510A-2 may be substantially parallel to one another.

The second metallization layer 510B may include a third conductive line 510B-1, which may be adjacent to masses of dielectric material 126. The third conductive line 510B-1 may have a longitudinal axis substantially along the second direction (e.g., along the y-axis in FIG. 5A), or substantially along a third direction parallel to the second direction.

The third metallization layer 510C may include a fourth conductive line 510C-1 and a fifth conductive line 510C-2, which may be separated by or adjacent to masses of dielectric material 126. The fourth and fifth conductive lines 510C-1, 510C-2 may have longitudinal axes along a fourth direction (e.g., along the x-axis in FIG. 5A) substantially perpendicular to or orthogonal to the second direction.

The fourth metallization layer 510D may include sixth and seventh conductive lines 510D-1, 510D-2, which may be separated by or adjacent to masses of dielectric material 126. The sixth and seventh conductive lines 510D-1, 510D-2 may have longitudinal axes substantially along the fourth direction (e.g., along the x-axis in FIG. 5A), or along a fifth direction substantially parallel to the fourth direction. The sixth and seventh conductive lines 510D-1, 510D-2 may be substantially parallel to one another.

FIG. 5B is a cross-sectional view of the IC device shown in FIG. 5A along plane B (e.g., along the z and x-axes). The first, second, third, and fourth conductive lines 510A-1, 510A-2, 510B-1, and 510C-1 are visible in FIG. 5B, and other conductive lines 128A are not visible in the view of plane B. Projection planes 512A, 512B, 512C, 512D (e.g., imaginary planes) along the z and y-axes (y-axis not shown in FIG. 5B, but shown in FIG. 5C as described further below) include sides of the conductive lines 510A-1, 510A-2, 510B-1, 510C-1. In particular, projection plane 512A includes a first side 513A of the first conductive line 510A-1 (as shown in FIG. 5C), projection planes 512B and 512C include first and second sides 513B, 513C of the third conductive line 510B-1, and projection plane 512D includes a first side 513D of the second conductive line 510A-2.

As shown in FIG. 5B, the projection planes 512A-512D are substantially parallel to the stack direction (e.g., along the z-axis) and substantially perpendicular to the longitudinal axes of the first, second, third, and fourth conductive lines 510A-1, 510A-2, 510B-1, 510C-1 (e.g., along the x- and y-axes). At least one projection plane (e.g., projection plane 512A) includes a portion of the first conductive line 510A-1, and does not include any portion of the third conductive line 510B-1, and at least one projection plane (e.g., projection plane 512B) includes a portion of the third conductive line 510B-1, and does not include any portion of the first conductive line 510A-1. In FIG. 5B, no projection plane substantially parallel to the stack direction (e.g., along the z-axis) and substantially perpendicular to the longitudinal axes of the first, second, third, and fourth conductive lines 510A-1, 510A-2, 510B-1, 510C-1 (e.g., along the x- and y-axes) includes both a portion of the first conductive line 510A-1 and a portion of the third conductive line 510B-1.

FIG. 5C is a view of a plane 520 (e.g., an imaginary plane along the y and x-axes, perpendicular to the first direction (e.g., along the z-axis)), and projections of the first, second, third, and fourth conductive lines 510A-1, 510A-2, 510B-1, and 510C-1 are shown on the plane 520. The projection planes 512A, 512B, 512C, 512D along the z- and y-axes (z-axis not shown in FIG. 5C, but shown in FIG. 5B) are shown at sides of the projections of the first, second, and third conductive lines 510A-1, 510A-2, and 510B-1 onto the plane 520. As shown, the projections of the first, second, and third conductive lines 510A-1, 510A-2, and 510B-1 onto the plane 520 are staggered or offset relative to one another. In particular, the projection of the first conductive line 510A-1 onto the plane 520 is offset with respect to the projection of the third conductive line 510B-1 onto the plane 520, and the projection of the third conductive line 510B-1 onto the plane 520 is offset with respect to the projection of the second conductive line 510A-2 onto the plane 520. The projection of the first conductive line 510A-1 onto the plane 520 does not overlap with the projection of the third conductive line 510B-1 onto the plane 520, and the projection of the third conductive line 510B-1 onto the plane 520 does not overlap with the projection of the second conductive line 510A-2 onto the plane 520. The projection of the fourth conductive line 510C-1 onto the plane 520 intersects the projections of the first, second and third conductive lines 510A-1, 510A-2, 510B-1 onto the plane 520.

Stated in another way, the plane 520 may be considered a superposed plane, the superposed plane including a superposition of a first superposition plane including a portion of the first conductive line 510A-1, a second superposition plane including a portion of the second conductive line 510A-2, a third superposition plane including a portion of the third conductive line 510B-1, and a fourth superposition plane including a portion of the fourth conductive line 510C-1, the first, second, third, and fourth superposition planes oriented substantially perpendicular to the stack direction (e.g., the first, second, third, and fourth superposition planes being oriented along the x-y axes perpendicular to the z-axis). In the superposed plane, the portion of the first conductive line 510A-1 and the portion of the third conductive line 510B-1 are separated, and occupy a larger portion of the superposed plane than either the portion of the first conductive line 510A-1 or the portion of the third conductive line 510B-1 individually. Furthermore, in the superposed plane, the portion of the third conductive line 510B-1 and the portion of the second conductive line 510A-2 are separated, and occupy a larger portion of the superposed plane than either the portion of the third conductive line 510B-1 or the portion of the second conductive line 510A-2 individually. In the superposed plane, the portion of the fourth conductive line 510C-1 is joined with the portions of the first, second, and third conductive lines 510A-1, 510A-2, 510B-1.

FIG. 5D is a cross-sectional view of the IC device shown in FIG. 5A along plane D (e.g., along the z and y-axes). The first, fourth, fifth, sixth, and seventh conductive lines 510A-1, 510C-1, 510C-2, 510D-1, 510D-2 are visible in FIG. 5D, and other conductive lines 128A are not visible in the view of plane D. Projection planes 514A, 514B, 514C, 514D, 514E, 514F (e.g., imaginary planes) along the z and x-axes (x-axis not shown in FIG. 5D, but shown in FIG. 5E as described further below) include sides of the fourth, fifth, sixth, and seventh conductive lines 510C-1, 510C-2, 510D-1, 510D-2. In particular, projection plane 514A includes a first side 515A of the fourth conductive line 510C-1 (as shown in FIG. 5E), projection planes 514B and 514C include first and second sides 515B, 515C of the sixth conductive line 510D-1, projection planes 514D and 514E include first and second sides 515D, 515E of the fifth conductive line 510C-2, and projection plane 514F includes a first side 515F of the seventh conductive line 510D-2.

As shown in FIG. 5D, the projection planes 514A-514F are substantially parallel to the stack direction (e.g., along the z-axis) and substantially perpendicular to the longitudinal axes of the first, fourth, fifth, sixth, and seventh conductive lines 510A-1, 510C-1, 510C-2, 510D-1, 510D-2 (e.g., along the x- and y-axes). At least one projection plane (e.g., projection plane 514A) includes a portion of the fourth conductive line 510C-1, and does not include any portion of the sixth conductive line 510D-1, and at least one projection plane (e.g., projection plane 514B) includes a portion of the sixth conductive line 510D-1, and does not include any portion of the fourth conductive line 510C-1. In FIG. 5D, no projection plane substantially parallel to the stack direction (e.g., along the z-axis) and substantially perpendicular to the longitudinal axes of the first, fourth, fifth, sixth, and seventh fifth conductive lines 510A-1, 510C-1, 510C-2, 510D-1, 510D-2 (e.g., along the x- and y-axes) includes both a portion of the fourth conductive line 510C-1 and a portion of the sixth conductive line 510D-1.

FIG. 5E is a view of a plane 530 (e.g., an imaginary plane along the x and y-axes, perpendicular to the first direction (e.g., along the z-axis)), and projections of the first, fourth, fifth, sixth, and seventh conductive lines 510A-1, 510C-1, 510C-2, 510D-1, 510D-2 are shown on the plane 530. The projection planes 514A, 514B, 514C, 514D, 514E, 514F along the z- and x-axes (z-axis not shown in FIG. 5E, but shown in FIG. 5D) are shown at sides of the projections of the fourth, fifth, sixth, and seventh conductive lines 510C-1, 510C-2, 510D-1, 510D-2 onto the plane 530. As shown, the projections of the fourth, fifth, sixth, and seventh conductive lines 510C-1, 510C-2, 510D-1, 510D-2 onto the plane 530 are staggered or offset relative to one another. In particular, the projection of the fourth conductive line 510C-1 onto the plane 530 is offset with respect to the projection of the sixth conductive line 510D-1 onto the plane 530, the projection of the sixth conductive line 510D-1 onto the plane 530 is offset with respect to the projection of the fifth conductive line 510C-2 onto the plane 530, and the projection of the fifth conductive line 510C-2 is offset with respect to the projection of the seventh conductive line 510D-2 onto the plane 530. The projection of the fourth conductive line 510C-1 onto the plane 530 does not overlap with the projection of the sixth conductive line 510D-1 onto the plane 530, the projection of the sixth conductive line 510D-1 onto the plane 530 does not overlap with the projection of the fifth conductive line 510C-2 onto the plane 530, and the projection of the fifth conductive line 510C-2 onto the plane 530 does not overlap with the projection of the seventh conductive line 510D-2 onto the plane 530. The projection of the first conductive line 510A-1 onto the plane 530 intersects the projections of the fourth, fifth, sixth, and seventh conductive lines 510C-1, 510C-2, 510D, 510D-2 onto the plane 530.

Stated in another way, the plane 530 may be considered a superposed plane, the superposed plane including a superposition of a first superposition plane including a portion of the first conductive line 510A-1, a second superposition plane including a portion of the fourth conductive line 510C-1, a third superposition plane including a portion of the fifth conductive line 510C-2, a fourth superposition plane including a portion of the sixth conductive line 510D-1, and a fifth superposition plane including a portion of the seventh conductive line 510D-2, the first, second, third, fourth, and fifth superposition planes oriented substantially perpendicular to the stack direction (e.g., the first, second, third, fourth, and fifth superposition planes being oriented along the x-y axes perpendicular to the z-axis). In the superposed plane, the portion of the fourth conductive line 510C-1 and the portion of the sixth conductive line 510D-1 are separated, and occupy a larger portion of the superposed plane than either the portion of the fourth conductive line 510C-1 or the portion of the sixth conductive line 510D-1 individually. Additionally, in the superposed plane, the portion of the sixth conductive line 510D-1 and the portion of the fifth conductive line 510C-2 are separated, and occupy a larger portion of the superposed plane than either the portion of the sixth conductive line 510D-1 or the portion of the fifth conductive line 510C-2 individually. Furthermore, in the superposed plane, the portion of the fifth conductive line 510C-2 and the portion of the seventh conductive line 510D-2 are separated, and occupy a larger portion of the superposed plane than either the portion of the fifth conductive line 510C-2 or the portion of the seventh conductive line 510D-2 individually. In the superposed plane, the portion of the first conductive line 510A-1 is joined with the portion of the fourth conductive line 510C-1, the portion of the fifth conductive line 510C-2, the portion of the sixth conductive line 510D-1, and the portion of the seventh conductive line 510D-2.

FIG. 6A is an isometric view of an alternative IC device 600 including a metallization stack having metallization layers with staggered conductive lines, in accordance with some embodiments. Parts of the alternative IC device 600, such as device layer 106, dielectric materials 126 and 206, conductive material 204, and so on, may be the same as presented in FIG. 2A and FIG. 5A and described above, and are not described further here in detail.

As shown in FIG. 6A, the IC device 600 includes the device layer 106 and the metallization stack 610, which may include the first metallization layer 610A, the second metallization layer 610B, the third metallization layer 610C, the fourth metallization layer 610D, the fifth metallization layer 610E, and the sixth metallization layer 610F. The metallization layers 610A-610F in the metallization stack 610 may be stacked along a first direction or a stack direction (e.g., along the z-axis as shown in FIG. 6A) over the device layer 106 (e.g., such that the first metallization layer 610A is over the device layer 106, the second metallization layer 610B is over the first metallization layer 610A, the third metallization layer 610C is over the second metallization layer 610B, the fourth metallization layer 610D is over the third metallization layer 610C, the fifth metallization layer 610E is over the fourth metallization layer 610D, and the sixth metallization layer 610F is over the fifth metallization layer 610E). The second metallization layer 610B may be between the first metallization layer 610A and the third metallization layer 610C, the third metallization layer 610C may be between the second metallization layer 610B and the fourth metallization layer 610D, the fourth metallization layer 610D may be between the third metallization layer 610C and the fifth metallization layer 610E, and the fifth metallization layer 610E may be between the fourth metallization layer 610D and the sixth metallization layer 610F. The metallization layers 610A-610F may be separated by layers of dielectric material 206, and may include conductive lines 128A and conductive vias 128B (the conductive vias 128B described above with reference to FIG. 1, but not shown in FIG. 6A). The conductive lines 128A may include the conductive material 204.

As shown, the first metallization layer 610A may include first and second conductive lines 610A-1 and 610A-2, which may be separated by or adjacent to masses of dielectric material 126. The first and second conductive lines 610A-1, 610A-2 may have longitudinal axes substantially along a second direction (e.g., along the y-axis in FIG. 2A) substantially perpendicular to or orthogonal to the first direction (e.g., the z-axis in FIG. 2A). Stated in a different way, the first and second conductive lines 610A-1, 610A-2 may extend substantially along the second direction, or the first and second conductive lines 610A-1, 610A-2 may be substantially elongated in the second direction. The first and second conductive lines 610A-1, 610A-2 may be substantially parallel to one another.

The second metallization layer 610B may include a third conductive line 610B-1, which may be adjacent to masses of dielectric material 126. The third conductive line 610B-1 may have a longitudinal axis substantially along the second direction (e.g., along the y-axis in FIG. 6A), or substantially along a third direction substantially parallel to the second direction.

The third metallization layer 610C may include a fourth conductive line 610C-1 and a fifth conductive line 610C-2, which may be separated by or adjacent to masses of dielectric material 126. The fourth conductive line 610C-1 and the fifth conductive line 610C-2 may have longitudinal axes substantially along the second direction (e.g., along the y-axis in FIG. 6A), or substantially along a fourth direction substantially parallel to the second direction.

The fourth metallization layer 610D may include a sixth conductive line 610D-1 and a seventh conductive line 610D-2, which may be separated by or adjacent to masses of dielectric material 126. The sixth conductive line 610D-1 and the seventh conductive lines 610D-2 may have longitudinal axes along a fifth direction (e.g., along the x-axis in FIG. 6A) substantially perpendicular to or orthogonal to the second direction.

The fifth metallization layer 610E may include eighth and ninth conductive lines 610E-1, 610E-2, which may be separated by or adjacent to masses of dielectric material 126. The eighth and ninth conductive lines 610E-1, 610E-2 may have longitudinal axes substantially along the fifth direction (e.g., along the x-axis in FIG. 6A), or along a sixth direction substantially parallel to the fifth direction. The eighth and ninth conductive lines 610E-1, 610E-2 may be substantially parallel to one another.

The sixth metallization layer 610F may include tenth and eleventh conductive lines 610F-1, 610F-2, which may be separated by or adjacent to masses of dielectric material 126. The tenth and eleventh conductive lines 610F-1, 610F-2 may have longitudinal axes substantially along the fifth direction (e.g., along the x-axis in FIG. 6A), or along a seventh direction substantially parallel to the fifth direction. The tenth and eleventh conductive lines 610F-1, 610F-2 may be substantially parallel to one another.

FIG. 6B is a cross-sectional view of the IC device shown in FIG. 6A along plane B (e.g., along the z and x-axes). The first, second, third, fourth, fifth, and eighth conductive lines 610A-1, 610A-2, 610B-1, 610C-1, 610C-2, 610E-1 are visible in FIG. 5B, and other conductive lines 128A are not visible in the view of plane B. Projection planes 612A, 612B, 612C, 612D (e.g., imaginary planes) along the z and y-axes (y-axis not shown in FIG. 6B, but shown in FIG. 6C as described further below) include sides of the conductive lines 610A-1, 610A-2, 610B-1, 610C-1, 610C-2. In particular, projection plane 612A includes a first side 613A of the first conductive line 610A-1 and a first side 613B of the fifth conductive line 610C-1, projection planes 612B and 612C include first and second sides 613C, 613D of the third conductive line 610B-1, and projection plane 612D includes a first side 613E of the second conductive line 610A-2 and a first side 613F of the fifth conductive line 610C-2.

As shown in FIG. 6B, the projection planes 612A-612D are substantially parallel to the stack direction (e.g., along the z-axis) and substantially perpendicular to the longitudinal axes of the first, second, third, fourth, fifth, and eighth conductive lines 610A-1, 610A-2, 610B-1, 610C-1, 610C-2, 610E-1 (e.g., along the x- and y-axes). At least one projection plane (e.g., projection plane 612A) includes a portion of the first conductive line 610A-1, and does not include any portion of the third conductive line 610B-1, and at least one projection plane (e.g., projection plane 612B) includes a portion of the third conductive line 610B-1, and does not include any portion of the first conductive line 610A-1. In FIG. 6B, no projection plane substantially parallel to the stack direction (e.g., along the z-axis) and substantially perpendicular to the longitudinal axes of the first, second, third, fourth, fifth, and eighth conductive lines 610A-1, 610A-2, 610B-1, 610C-1, 610C-2, 610E-1 (e.g., along the x- and y-axes) includes both a portion of the first conductive line 610A-1 and a portion of the third conductive line 610B-1.

FIG. 6C is a view of a plane 620 (e.g., an imaginary plane along the y and x-axes, perpendicular to the first direction (e.g., along the z-axis)), and projections of the first, second, third, fourth, fifth, and eighth conductive lines 610A-1, 610A-2, 610B-1, 610C-1, 610C-2, 610E-1 are shown on the plane 620 (i.e., with the projections of the first and fourth conductive lines 610A-1, 610C-1 overlapping, and the projections of the second and fifth conductive lines 610A-2, 610C-2 overlapping). The projection planes 612A, 612B, 612C, 612D along the z- and y-axes (z-axis not shown in FIG. 6C, but shown in FIG. 6B) are shown at sides of the projections of the first, second, third, fourth, and fifth conductive lines 610A-1, 610A-2, 610B-1, 610C-1, 610C-2 onto the plane 620. As shown, the projections of the first, second, third, fourth, and fifth conductive lines 610A-1, 610A-2, 610B-1, 610C-1, 610C-2 onto the plane 620 are staggered or offset relative to one another. In particular, the projections of the first conductive line 610A-1 and the fourth conductive line 610C-1 onto the plane 620 are offset with respect to the projection of the third conductive line 610B-1 onto the plane 620, and the projection of the third conductive line 610B-1 onto the plane 620 is offset with respect to the projections of the second conductive line 610A-2 and the fifth conductive line 610C-2 onto the plane 620. The projections of the first conductive line 610A-1 and the fourth conductive line 610C-1 onto the plane 620 do not overlap with the projection of the third conductive line 610B-1 onto the plane 620, and the projection of the third conductive line 610B-1 onto the plane 620 does not overlap with the projections of the second conductive line 610A-2 and the fifth conductive line 610C-2 onto the plane 620. The projection of the eighth conductive line 610E-1 onto the plane 620 intersects the projection of the first, second, third, fourth, and fifth conductive lines 610A-1, 610A-2, 610B-1, 610C-1, 610C-2 onto the plane 620.

Stated in another way, the plane 620 may be considered a superposed plane, the superposed plane including a superposition of a first superposition plane including a portion of the first conductive line 610A-1, a second superposition plane including a portion of the second conductive line 610A-2, a third superposition plane including a portion of the third conductive line 610B-1, a fourth superposition plane including a portion of the fourth conductive line 610B-2, a fifth superposition plane including a portion of the fifth conductive line 610C-1, and a sixth superposition plane including a portion of the eighth conductive line 610E-1, the first, second, third, fourth, fifth, and sixth superposition planes oriented substantially perpendicular to the stack direction (e.g., the first, second, third, fourth, fifth, and sixth superposition planes being oriented along the x-y axes perpendicular to the z-axis). In the superposed plane, the portions of the first conductive line 610A-1 and the fourth conductive line 610C-1 are joined, and are separated from the portion of the third conductive line 610B-1. The portion of the first conductive line 610A-1 (or the fourth conductive line 610C-1) and the portion of the third conductive line 610B-1 occupy a larger portion of the superposed plane than either the portion of the first conductive line 610A-1 (or the fourth conductive line 610C-1) or the portion of the third conductive line 610B-1 individually. Furthermore, in the superposed plane, the portions of the second conductive line 610A-2 and the fifth conductive line 610C-2 are joined, and are separated from the portion of the third conductive line 610B-1. The second conductive line 610A-2 (or the fifth conductive line 610C-2) and the third conductive line 610B-1 occupy a larger portion of the superposed plane than either the portion of the second conductive line 610A-2 (or the fifth conductive line 610C-2) or the portion of the third conductive line 610B-1 individually. In the superposed plane, the portion of the eighth conductive line 610E-1 is joined with the portions of the first, second, third, fourth, and fifth conductive lines 610A-1, 610A-2, 610B-1, 610C-1, 610C-2.

FIG. 6D is a cross-sectional view of the IC device shown in FIG. 6A along plane D (e.g., along the z and y-axes). The first, fourth, sixth, seventh, eighth, ninth, tenth, and eleventh conductive lines 610A-1, 610C-1, 610D-1, 610D-2, 610E-1, 610E-2, 610F-1, 610F-2 are visible in FIG. 6D, and other conductive lines 128A are not visible in the view of plane D. Projection planes 614A, 614B, 614C, 614D, 614E, 614F (e.g., imaginary planes) along the z and x-axes (x-axis not shown in FIG. 6D, but shown in FIG. 6E as described further below) include sides of the sixth, seventh, eighth, ninth, tenth, and eleventh conductive lines 610D-1, 610D-2, 610E-1, 610E-2, 610F-1, 610F-2. In particular, projection plane 614A includes a first side 615A of the eighth conductive line 610E-1 (as seen in FIG. 6E), projection plane 614B includes a first side 615B of the sixth conductive line 610D-1 and a first side 615C of the tenth conductive line 610F-1, projection plane 614C includes a second side 615D of the sixth conductive line 610D-1 and a second side 615E of the tenth conductive line 610F-1, projection plane 614D includes a first side 615F of the ninth conductive line 610E-2, projection plane 614E includes a second side 615G of the ninth conductive line 610E-2, and projection plane 614F includes a first side 615H of the seventh conductive line 610C-2 and a first side 615I of the eleventh conductive line 610F-2.

As shown in FIG. 6D, the projection planes 614A-614F are substantially parallel to the stack direction (e.g., along the z-axis) and substantially perpendicular to the longitudinal axes of the first, fourth, sixth, seventh, eighth, ninth, tenth, and eleventh conductive lines 610A-1, 610C-1, 610D-1, 610D-2, 610E-1, 610E-2, 610F-1, 610F-2 (e.g., along the x- and y-axes). At least one projection plane (e.g., projection plane 614A) includes a portion of the eighth conductive line 610E-1, and does not include any portion of the sixth conductive line 610D-1 (or the tenth conductive line 610F-1), and at least one projection plane (e.g., projection plane 614B) includes a portion of the sixth conductive line 610D-1 (and a portion of the tenth conductive line 610F-1), and does not include any portion of the eighth conductive line 610E-1. In FIG. 6D, no projection plane substantially parallel to the stack direction (e.g., along the z-axis) and substantially perpendicular to the longitudinal axes of the first, fourth, sixth, seventh, eighth, ninth, tenth, and eleventh conductive lines 610A-1, 610C-1, 610D-1, 610D-2, 610E-1, 610E-2, 610F-1, 610F-2 (e.g., along the x- and y-axes) includes both a portion of the eighth conductive line 610E-1 and a portion of the sixth conductive line 610D-1 (or the tenth conductive line 610F-1).

FIG. 6E is a view of a plane 630 (e.g., an imaginary plane along the x and y-axes, perpendicular to the first direction (e.g., along the z-axis)), and projections of the first, fourth, sixth, seventh, eighth, ninth, tenth, and eleventh conductive lines 610A-1, 610C-1, 610D-1, 610D-2, 610E-1, 610E-2, 610F-1, 610F-2 are shown on the plane 630. The projection planes 614A, 614B, 614C, 614D, 614E, 614F along the z- and x-axes (z-axis not shown in FIG. 6E, but shown in FIG. 6D) are shown at sides of the projections of the sixth, seventh, eighth, ninth, tenth, and eleventh conductive lines 610D-1, 610D-2, 610E-1, 610E-2, 610F-1, 610F-2 onto the plane 630. As shown, the projections of the sixth, seventh, eighth, ninth, tenth, and eleventh conductive lines 610D-1, 610D-2, 610E-1, 610E-2, 610F-1, 610F-2 onto the plane 630 are staggered or offset relative to one another. In particular, the projection of the eighth conductive line 610E-1 onto the plane 630 is offset with respect to the projections of the sixth and tenth conductive lines 610D-1, 610F-1 onto the plane 630, the projections of the sixth and tenth conductive lines 610D-1, 610F-1 onto the plane 630 are offset with respect to the projection of the ninth conductive line 610E-2 onto the plane 630, and the projection of the ninth conductive line 610E-2 is offset with respect to the projections of the seventh and eleventh conductive lines 610D-2, 610F-2 onto the plane 630. The projection of the eighth conductive line 610E-1 onto the plane 630 does not overlap with the projections of the sixth conductive line 610D-1 and the tenth conductive line 610F-1 onto the plane 630, the projections of the sixth conductive line 610D-1 and the tenth conductive line 610F-1 onto the plane 630 do not overlap with the projection of the ninth conductive line 610E-2 onto the plane 530, and the projection of the ninth conductive line 610E-2 onto the plane 630 does not overlap with the projections of the seventh conductive line 610D-2 or the eleventh conductive line 610F-2 onto the plane 630. The projections of the first and fourth conductive lines 610A-1, 610C-1 onto the plane 630 (which overlap with one another) intersect the projections of the sixth, seventh, eighth, ninth, tenth, and eleventh conductive lines 610D-1, 610D-2, 610E-1, 610E-2, 610F-1, 610F-2 onto the plane 630.

Stated in another way, the plane 630 may be considered a superposed plane, the superposed plane including a superposition of a first superposition plane including a portion of the first conductive line 610A-1, a second superposition plane including a portion of the fourth conductive line 610C-1, a third superposition plane including a portion of the sixth conductive line 610D-1, a fourth superposition plane including a portion of the seventh conductive line 610D-2, a fifth superposition plane including a portion of the eighth conductive line 610E-1, a sixth superposition plane including a portion of the ninth conductive line 610E-2, a seventh superposition plane including a portion of the tenth conductive line 610F-1, and an eighth superposition plane including a portion of the eleventh conductive line 610F-2, the first through eighth superposition planes oriented substantially perpendicular to the stack direction (e.g., the first through eighth superposition planes being oriented along the x-y axes perpendicular to the z-axis).

In the superposed plane, the portion of the eighth conductive line 610E-1 and the portion of the sixth conductive line 610D-1 (or the tenth conductive line 610F-1) are separated, and occupy a larger portion of the superposed plane than either the portion of the eighth conductive line 610E-1 or the portion of the sixth conductive line 610D-1 (or the portion of the tenth conductive line 610F-1) individually. Additionally, in the superposed plane, the portion of the sixth conductive line 610D-1 (or the portion of the tenth conductive line 610F-1) and the portion of the ninth conductive line 610E-2 are separated, and occupy a larger portion of the superposed plane than either the portion of the sixth conductive line 610D-1 (or the portion of the tenth conductive line 610F-1) or the portion of the ninth conductive line 610E-2 individually. Furthermore, in the superposed plane, the portion of the ninth conductive line 610E-2 and the portion of the seventh conductive line 610D-2 (or the portion of the eleventh conductive line 610F-2) are separated, and occupy a larger portion of the superposed plane than either the portion of the ninth conductive line 610E-2 or the portion of the seventh conductive line 610D-2 (or the portion of the eleventh conductive line 610F-2) individually. In the superposed plane, the portions of the first and fourth conductive lines 610A-1, 610C-1 are joined with the portions of the sixth, seventh, eighth, ninth, tenth, and eleventh conductive lines 610D-1, 610D-2, 610E-1, 610E-2, 610F-1, 610F-2.

As described above, FIG. 6 shows an IC device 600 including a metallization stack 610 including six metallization layers 610A-610F stacked along a first direction (e.g., along the z-axis). Metallization layers in three of the metallization layers 610A-610C have conductive lines extending in a second direction (e.g., along the y-axis), and conductive lines in adjacent metallization layers of the metallization layers 610A-610C are staggered relative to one another (e.g., where the first and second conductive lines 610A-1, 610A-2 of the first metallization layer 610A are staggered relative to the third conductive line 610B-1 of the second metallization layer 610B, and the third conductive line 610B-1 of the second metallization layer 610B is staggered relative to the fourth conductive line 610C-1 and the fifth conductive line 610C-2 of the third metallization layer 610C). Metallization layers in three of the metallization layers 610D-610F have conductive lines extending in a third direction perpendicular to the second direction and the first direction (e.g., along the x-axis), where the conductive lines in adjacent metallization layers of the metallization layers 610D-610F are staggered relative to one another (e.g., where the sixth and seventh conductive lines 610D-1, 610D-2 of the fourth metallization layer 610D are staggered relative to the eighth and ninth conductive lines 610E-1, 610E-2 of the fifth metallization layer 610E, and the eighth and ninth conductive lines 610E-1, 610E-2 of the fifth metallization layer 610E are staggered relative to the tenth and eleventh conductive lines 610F-1, 610F-2 of the sixth metallization layer 610F). Such an IC device 600 may be described as having a 3×3 configuration (e.g., having a first sub-stack including three metallization layers with staggered conductive lines extending in the second direction, and a second sub-stack over the first sub-stack including three metallization layers with staggered conductive lines extending in the third direction). In some embodiments, IC devices may include additional metallization layers in a given yxz configuration (e.g., 4×4, 5×5, etc.), or additional metallization sub-stacks may be included (e.g., 3×3×3, 4×4×4, 4×6×8, etc.)

Arrangements with one or more metallization stacks having metallization layers with staggered conductive lines as disclosed herein may be included in any suitable electronic device. FIGS. 7-10 illustrate various examples of devices and components that may include one or more metallization stacks having metallization layers with staggered conductive lines as disclosed herein.

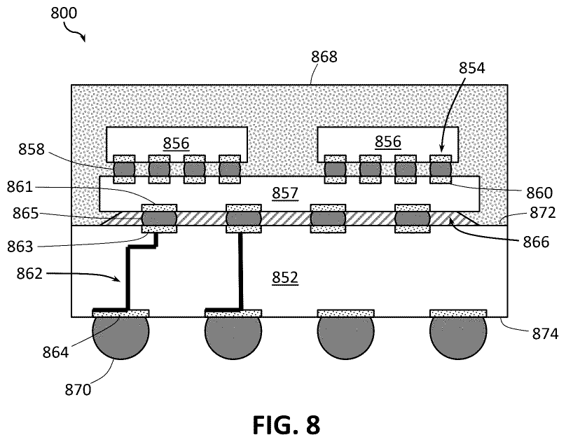

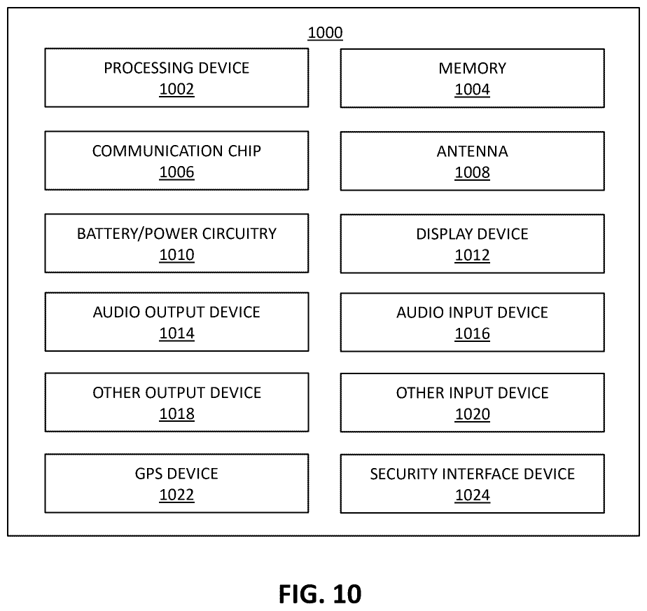

FIGS. 7A-7B are top views of a wafer 700 and dies 702 that may include one or more metallization stacks having metallization layers with staggered conductive lines in accordance with any of the embodiments disclosed herein. In some embodiments, the dies 702 may be included in an IC package, in accordance with any of the embodiments disclosed herein. For example, any of the dies 702 may serve as any of one or more dies 856 in an IC package 800 shown in FIG. 8. The wafer 700 may be composed of semiconductor material and may include one or more dies 702 having IC structures formed on a surface of the wafer 700. Each of the dies 702 may be a repeating unit of a semiconductor product that includes any suitable IC (e.g., ICs including one or more metallization stacks having metallization layers with staggered conductive lines as described herein). After the fabrication of the semiconductor product is complete (e.g., after manufacture of one or more layers of the metallization stacks having metallization layers with staggered conductive lines as described herein), the wafer 700 may undergo a singulation process in which each of the dies 702 is separated from one another to provide discrete “chips” of the semiconductor product. In particular, devices that include one or more metallization stacks having metallization layers with staggered conductive lines as disclosed herein may take the form of the wafer 700 (e.g., not singulated) or the form of the die 702 (e.g., singulated). The die 702 may include supporting circuitry to route electrical signals to various memory cells, transistors, capacitors, as well as any other IC components. In some embodiments, the wafer 700 or the die 702 may implement or include a memory device (e.g., a static random access memory (SRAM) device), a logic device (e.g., an AND, OR, NAND, or NOR gate), or any other suitable circuit element. Multiple ones of these devices may be combined on a single die 702. For example, a memory array formed by multiple memory devices may be formed on a same die 702 as a processing device (e.g., the processing device 1002 of FIG. 10) or other logic that is configured to store information in the memory devices or execute instructions stored in the memory array.

FIG. 8 is a side, cross-sectional view of an example IC package 800 that may include one or more metallization stacks having metallization layers with staggered conductive lines in accordance with any of the embodiments disclosed herein. In some embodiments, the IC package 800 may be a system-in-package (SiP).

The IC package 800 may include a package substrate 852 which may be formed of a dielectric material (e.g., a ceramic, a buildup film, an epoxy film having filler particles therein, etc.), and may have conductive pathways extending through the dielectric material between a face 872 and a face 874, or between different locations on the face 872, and/or between different locations on the face 874.

The package substrate 852 may include conductive contacts 863 that are coupled to conductive pathways 862 through the package substrate 852, allowing circuitry within dies 856 and/or an interposer 857 to electrically couple to various ones of the conductive contacts 864 (or to other devices included in the package substrate 852, not shown).

As noted above, the IC package 800 may include an interposer 857, which may be coupled to the package substrate 852 through conductive contacts 861 of the interposer 857, first-level interconnects 865, and the conductive contacts 863 of the package substrate 852. The first-level interconnects 865 illustrated in FIG. 8 are solder bumps, but any suitable first-level interconnects 865 may be used. In some embodiments, no interposer 857 may be included in the IC package 800; instead, the dies 856 may be coupled directly to the conductive contacts 863 at the face 872 by first-level interconnects 865.

The IC package 800 may include one or more dies 856 coupled to the interposer 857 via conductive contacts 854 of the dies 856, first-level interconnects 858, and conductive contacts 860 of the interposer 857. The conductive contacts 860 may be coupled to conductive pathways (not shown) through the interposer 857, allowing circuitry within the dies 856 to electrically couple to various ones of the conductive contacts 861 (or to other devices included in the interposer 857, not shown). As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

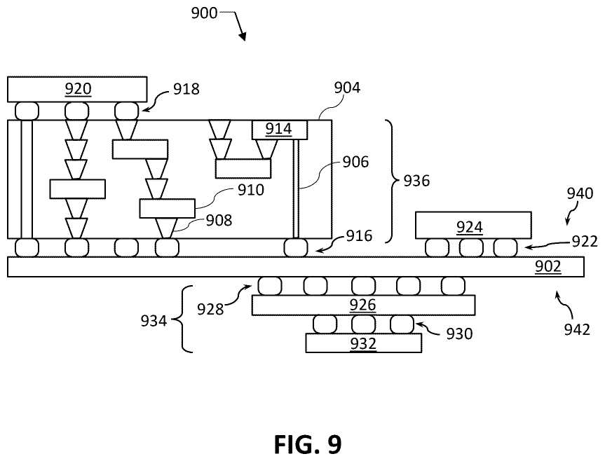

In some embodiments, an underfill material 866 may be disposed between the package substrate 852 and the interposer 857 around the first-level interconnects 865, and a mold compound 868 may be disposed around the dies 856 and the interposer 857 and in contact with the package substrate 852. In some embodiments, the underfill material 866 may be the same as the mold compound 868. Example materials that may be used for the underfill material 866 and the mold compound 868 are epoxy mold materials, as suitable. Second-level interconnects 870 may be coupled to the conductive contacts 864. The second-level interconnects 870 illustrated in FIG. 8 are solder balls (e.g., for a ball grid array arrangement), but any suitable second-level interconnects 870 may be used (e.g., pins in a pin grid array arrangement or lands in a land grid array arrangement). The second-level interconnects 870 may be used to couple the IC package 800 to another component, such as a circuit board (e.g., a motherboard), an interposer, or another IC package, as known in the art and as discussed below with reference to FIG. 9.

The dies 856 may take the form of any of the embodiments of the die 702 discussed herein (e.g., may include any of the embodiments of the metallization stacks having metallization layers with staggered conductive lines as described herein). In embodiments in which the IC package 800 includes multiple dies 856, the IC package 800 may be referred to as a multi-chip package (MCP). The dies 856 may include circuitry to perform any desired functionality. For example, one or more of the dies 856 may be logic dies (e.g., silicon-based dies), and one or more of the dies 856 may be memory dies (e.g., high bandwidth memory). In some embodiments, any of the dies 856 may include one or more metallization stacks having metallization layers with staggered conductive lines as discussed above; in some embodiments, at least some of the dies 856 may not include any metallization stacks having metallization layers with staggered conductive lines.

The IC package 800 illustrated in FIG. 8 may be a flip chip package, although other package architectures may be used. For example, the IC package 800 may be a ball grid array (BGA) package, such as an embedded wafer-level ball grid array (eWLB) package. In another example, the IC package 800 may be a wafer-level chip scale package (WLCSP) or a panel fan-out (FO) package. Although two dies 856 are illustrated in the IC package 800 of FIG. 8, an IC package 800 may include any desired number of the dies 856. An IC package 800 may include additional passive components, such as surface-mount resistors, capacitors, and inductors disposed on the first face 872 or the second face 874 of the package substrate 852, or on either face of the interposer 857. More generally, an IC package 800 may include any other active or passive components known in the art.

FIG. 9 is a cross-sectional side view of an IC device assembly 900 that may include components having one or more metallization stacks having metallization layers with staggered conductive lines in accordance with any of the embodiments disclosed herein. The IC device assembly 900 includes a number of components disposed on a circuit board 902 (which may be, e.g., a motherboard). The IC device assembly 900 includes components disposed on a first face 940 of the circuit board 902 and an opposing second face 942 of the circuit board 902; generally, components may be disposed on one or both faces 940 and 942. In particular, any suitable ones of the components of the IC device assembly 900 may include any of one or more metallization stacks having metallization layers with staggered conductive lines in accordance with any of the embodiments disclosed herein; e.g., any of the IC packages discussed below with reference to the IC device assembly 900 may take the form of any of the embodiments of the IC package 800 discussed above with reference to FIG. 8 (e.g., may include one or more metallization stacks having metallization layers with staggered conductive lines provided on a die 856, which may be the same as the die 702 of FIG. 7).

In some embodiments, the circuit board 902 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 902. In other embodiments, the circuit board 902 may be a non-PCB substrate.

The IC device assembly 900 illustrated in FIG. 9 includes a package-on-interposer structure 936 coupled to the first face 940 of the circuit board 902 by coupling components 916. The coupling components 916 may electrically and mechanically couple the package-on-interposer structure 936 to the circuit board 902, and may include solder balls (e.g., as shown in FIG. 9), male and female portions of a socket, an adhesive, an underfill material, and/or any other suitable electrical and/or mechanical coupling structure.

The package-on-interposer structure 936 may include an IC package 920 coupled to an interposer 904 by coupling components 918. The coupling components 918 may take any suitable form for the application, such as the forms discussed above with reference to the coupling components 916. The IC package 920 may be or include, for example, a die (the die 702 of FIG. 7), an IC device, or any other suitable component. In particular, the IC package 920 may include one or more metallization stacks having metallization layers with staggered conductive lines as described herein. Although a single IC package 920 is shown in FIG. 9, multiple IC packages may be coupled to the interposer 904; indeed, additional interposers may be coupled to the interposer 904. The interposer 904 may provide an intervening substrate used to bridge the circuit board 902 and the IC package 920. Generally, the interposer 904 may spread a connection to a wider pitch or reroute a connection to a different connection. For example, the interposer 904 may couple the IC package 920 (e.g., a die) to a BGA of the coupling components 916 for coupling to the circuit board 902. In the embodiment illustrated in FIG. 9, the IC package 920 and the circuit board 902 are attached to opposing sides of the interposer 904; in other embodiments, the IC package 920 and the circuit board 902 may be attached to a same side of the interposer 904. In some embodiments, three or more components may be interconnected by way of the interposer 904.

The interposer 904 may be formed of an epoxy resin, a fiberglass-reinforced epoxy resin, a ceramic material, or a polymer material such as polyimide. In some implementations, the interposer 904 may be formed of alternate rigid or flexible materials that may include the same materials described above for use in a semiconductor substrate, such as silicon, germanium, and other group III-V and group IV materials. The interposer 904 may include metal interconnects 908 and vias 910, including but not limited to through-silicon vias (TSVs) 906. The interposer 904 may further include embedded devices 914, including both passive and active devices. Such devices may include, but are not limited to, capacitors, decoupling capacitors, resistors, inductors, fuses, diodes, transformers, sensors, electrostatic discharge (ESD) protection devices, and memory devices. More complex devices such as radio frequency (RF) devices, power amplifiers, power management devices, antennas, arrays, sensors, and microelectromechanical systems (MEMS) devices may also be formed on the interposer 904. The package-on-interposer structure 936 may take the form of any of the package-on-interposer structures known in the art.

The IC device assembly 900 may include an IC package 924 coupled to the first face 940 of the circuit board 902 by coupling components 922. The coupling components 922 may take the form of any of the embodiments discussed above with reference to the coupling components 916, and the IC package 924 may take the form of any of the embodiments discussed above with reference to the IC package 920.

The IC device assembly 900 illustrated in FIG. 9 includes a package-on-package structure 934 coupled to the second face 942 of the circuit board 902 by coupling components 928. The package-on-package structure 934 may include an IC package 926 and an IC package 932 coupled together by coupling components 930 such that the IC package 926 is disposed between the circuit board 902 and the IC package 932. The coupling components 928 and 930 may take the form of any of the embodiments of the coupling components 916 discussed above, and the IC packages 926 and 932 may take the form of any of the embodiments of the IC package 920 discussed above. The package-on-package structure 934 may be configured in accordance with any of the package-on-package structures known in the art.

FIG. 10 is a block diagram of an example computing device 1000 that may include one or more components with one or more metallization stacks having metallization layers with staggered conductive lines in accordance with any of the embodiments disclosed herein. For example, any suitable ones of the components of the computing device 1000 may include a die (e.g., the die 702, shown in FIG. 7) including one or more metallization stacks having metallization layers with staggered conductive lines in accordance with any of the embodiments disclosed herein. Any of the components of the computing device 1000 may include an IC package 800 (e.g., as shown in FIG. 8). Any of the components of the computing device 1000 may include an IC device assembly 900 (e.g., as shown in FIG. 9). Any of the components of the computing device 1000 may include an IC device 100 (e.g., as shown in FIG. 1).

A number of components are illustrated in FIG. 10 as included in the computing device 1000, but any one or more of these components may be omitted or duplicated, as suitable for the application. In some embodiments, some or all of the components included in the computing device 1000 may be attached to one or more motherboards. In some embodiments, some or all of these components are fabricated onto a single system-on-a-chip (SoC) die.

Additionally, in various embodiments, the computing device 1000 may not include one or more of the components illustrated in FIG. 10, but the computing device 1000 may include interface circuitry for coupling to the one or more components. For example, the computing device 1000 may not include a display device 1012, but may include display device interface circuitry (e.g., a connector and driver circuitry) to which a display device 1012 may be coupled. In another set of examples, the computing device 1000 may not include an audio input device 1016 or an audio output device 1014, but may include audio input or output device interface circuitry (e.g., connectors and supporting circuitry) to which an audio input device 1016 or audio output device 1014 may be coupled.

The computing device 1000 may include a processing device 1002 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1002 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices. The computing device 1000 may include a memory 1004, which may itself include one or more memory devices such as volatile memory (e.g., DRAM), nonvolatile memory (e.g., read-only memory (ROM)), flash memory, solid state memory, and/or a hard drive. In some embodiments, the memory 1004 may include memory that shares a die with the processing device 1002.

In some embodiments, the computing device 1000 may include a communication chip 1006 (e.g., one or more communication chips). For example, the communication chip 1006 may be configured for managing wireless communications for the transfer of data to and from the computing device 1000. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1006 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1006 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1006 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1006 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1006 may operate in accordance with other wireless protocols in other embodiments. The computing device 1000 may include an antenna 1008 to facilitate wireless communications and/or to receive other wireless communications (such as AM or FM radio transmissions).

In some embodiments, the communication chip 1006 may manage wired communications, such as electrical, optical, or any other suitable communication protocols (e.g., the Ethernet). As noted above, the communication chip 1006 may include multiple communication chips. For instance, a first communication chip 1006 may be dedicated to shorter-range wireless communications such as Wi-Fi or Bluetooth, and a second communication chip 1006 may be dedicated to longer-range wireless communications such as global positioning system (GPS), EDGE, GPRS, CDMA, WiMAX, LTE, EV-DO, or others. In some embodiments, a first communication chip 1006 may be dedicated to wireless communications, and a second communication chip 1006 may be dedicated to wired communications.

The computing device 1000 may include battery/power circuitry 1010. The battery/power circuitry 1010 may include one or more energy storage devices (e.g., batteries or capacitors) and/or circuitry for coupling components of the computing device 1000 to an energy source separate from the computing device 1000 (e.g., AC line power).

The computing device 1000 may include a display device 1012 (or corresponding interface circuitry, as discussed above). The display device 1012 may include any visual indicators, such as a heads-up display, a computer monitor, a projector, a touchscreen display, a liquid crystal display (LCD), a light-emitting diode display, or a flat panel display, for example.

The computing device 1000 may include an audio output device 1014 (or corresponding interface circuitry, as discussed above). The audio output device 1014 may include any device that generates an audible indicator, such as speakers, headsets, or earbuds, for example.

The computing device 1000 may include an audio input device 1016 (or corresponding interface circuitry, as discussed above). The audio input device 1016 may include any device that generates a signal representative of a sound, such as microphones, microphone arrays, or digital instruments (e.g., instruments having a musical instrument digital interface (MIDI) output).

The computing device 1000 may include a GPS device 1022 (or corresponding interface circuitry, as discussed above). The GPS device 1022 may be in communication with a satellite-based system and may receive a location of the computing device 1000, as known in the art.

The computing device 1000 may include an other output device 1018 (or corresponding interface circuitry, as discussed above). Examples of the other output device 1018 may include an audio codec, a video codec, a printer, a wired or wireless transmitter for providing information to other devices, or an additional storage device.

The computing device 1000 may include an other input device 1020 (or corresponding interface circuitry, as discussed above). Examples of the other input device 1020 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 1000 may include a security interface device 1024 (or corresponding interface circuitry, as discussed above). The security interface device 1024 may include any device that provides security features for the computing device 1000 or for any individual components therein (e.g., for the processing device 1002 or for the memory 1004). Examples of security features may include authorization, access to digital certificates, access to items in keychains, etc. Examples of the security interface device 1024 may include a software firewall, a hardware firewall, an antivirus, a content filtering device, or an intrusion detection device.

The computing device 1000 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 1000 may be any other electronic device that processes data.

The following paragraphs provide various examples of the embodiments disclosed herein.

Example 1 provides an IC structure, the IC structure including a first metallization layer including a first conductive line; a second metallization layer including a second conductive line; and a third metallization layer including a third conductive line, where: the first metallization layer, the second metallization layer, and the third metallization layer are stacked along a direction, the second metallization layer is between the first metallization layer and the third metallization layer, a projection of the first conductive line onto a plane perpendicular to the direction is offset with respect to a projection of the third conductive line onto the plane, and a projection of the second conductive line onto the plane intersects the projection of the first conductive line onto the plane and the projection of the third conductive line onto the plane.

Example 2 provides the IC structure of example 1, where the projection of the first conductive line onto the plane and the projection of the third conductive line onto the plane do not overlap.

Example 3 provides the IC structure of example 1, where the projection of the first conductive line onto the plane and the projection of the third conductive line onto the plane partially overlap.

Example 4 provides the IC structure of any one of examples 1-3, where the direction is a first direction, the first conductive line has a longitudinal axis along a second direction, the second conductive line has a longitudinal axis along a third direction, and the second direction is substantially perpendicular to the third direction.

Example 5 provides the IC structure of any one of examples 1-3, where the direction is a first direction, the first conductive line has a longitudinal axis along a second direction, the third conductive line has a longitudinal axis along a third direction, and the second direction is substantially parallel to the third direction.

Example 6 provides the IC structure of any one of examples 1-5, where the first metallization layer further includes a fourth conductive line, and a projection of the fourth conductive line onto the plane is offset with respect to the projection of the third conductive line onto the plane.

Example 7 provides the IC structure of example 6, where the first conductive line is substantially parallel to the fourth conductive line.

Example 8 provides the IC structure of any one of examples 1-5, further including a fourth metallization layer including a fourth conductive line, where the third metallization layer is between the second metallization layer and the fourth metallization layer, and the projection of the second conductive line onto the plane is offset with respect to a projection of the fourth conductive line onto the plane.

Example 9 provides the IC structure of example 8, where the projection of the third conductive line onto the plane intersects the projection of the second conductive line onto the plane and the projection of the fourth conductive line onto the plane.

Example 10 provides the IC structure of examples 8 or 9, where the projection of the second conductive line onto the plane and the projection of the fourth conductive line onto the plane do not overlap.

Example 11 provides the IC structure of examples 8 or 9, where the projection of the second conductive line onto the plane and the projection of the fourth conductive line onto the plane partially overlap.

Example 12 provides an IC structure, the IC structure including a first layer including a first conductive feature, the first conductive feature elongated in a first direction; a second layer over the first layer, the second layer including a second conductive feature; and a third layer over the second layer, the third layer including a third conductive feature, the third conductive feature elongated in the first direction, where: the first layer, the second layer, and the third layer are stacked along a second direction, and in a superposed plane including a superposition of a first plane including a portion of the first conductive feature, a second plane including a portion of the second conductive feature, and a third plane including a portion of the third conductive feature, each of the first, second, and third planes oriented substantially perpendicular to the second direction, the portion of the first conductive feature and the portion of the third conductive feature occupy a larger portion of the superposed plane than either the portion of the first conductive feature or the portion of the third conductive feature individually, and the portion of the second conductive feature is joined with the portion of the first conductive feature and with the portion of the third conductive feature in the superposed plane.

Example 13 provides the IC structure of example 12, where the second conductive feature is elongated in a third direction, the first direction substantially perpendicular to the third direction.

Example 14 provides the IC structure of examples 12 or 13, where the portions of the first conductive feature and the third conductive feature in the superposed plane are separated.

Example 15 provides the IC structure of examples 12 or 13, where the portions of the first conductive feature and the third conductive feature in the superposed plane are joined.

Example 16 provides the IC structure of any one of examples 12-15, further including a fourth layer including a fourth conductive feature, where the superposed plane further includes a superposition of a fourth plane, the fourth plane oriented substantially perpendicular to the second direction and including a portion of the fourth conductive feature, and the portions of the second conductive feature and the fourth conductive feature occupy a larger portion of the superposed plane than either the portion of the second conductive feature or the portion of the fourth conductive feature individually.

Example 17 provides the IC structure of example 16, where the portion of the third conductive feature is joined with the portion of the second conductive feature and with the portion of the fourth conductive feature in the superposed plane.

Example 18 provides the IC structure of examples 16 or 17, where the second conductive feature and the fourth conductive feature are elongated and substantially parallel to one another.

Example 19 provides the IC structure of any one of examples 16-18, where the portions of the second conductive feature and the fourth conductive feature in the superposed plane are separated.

Example 20 provides the IC structure of any one of examples 16-18, where the portions of the second conductive feature and the fourth conductive feature in the superposed plane are joined.

Example 21 provides an IC structure, the IC structure including a first conductive element extending substantially along a first direction; a second conductive element extending substantially along a second direction; and a third conductive element extending substantially along the first direction, where: the second conductive element is between the first conductive element and the third conductive element, at least one plane substantially perpendicular to both the first direction and second direction includes a portion of the first conductive element and does not include any portion of the third conductive element, and at least one plane substantially perpendicular to both the first direction and a second direction includes a portion of the third conductive element and does not include any portion of the first conductive element.

Example 22 provides the IC structure of example 21, where no plane perpendicular to both the first direction and the second direction includes both a portion of the first conductive element and a portion of the third conductive element.

Example 23 provides the IC structure of example 21, where a plane perpendicular to both the first direction and the second direction includes a portion of the first conductive element and a portion of the third conductive element.

Example 24 provides the IC structure of any one of examples 21-23, where the first direction is substantially orthogonal to the second direction.

Example 25 provides the IC structure of any one of examples 21-24, further including a fourth conductive element, where the third conductive element is between the second conductive element and the fourth conductive element, at least one plane substantially perpendicular to both the first direction and the second direction includes a portion of the second conductive element and does not include any portion of the fourth conductive element, and at least one plane substantially perpendicular to both the first direction and the second direction includes a portion of the fourth conductive element and does not include any portion of the second conductive element.

Example 26 provides the IC structure of example 25, where no plane perpendicular to both the first direction and the second direction includes both a portion of the second conductive element and a portion of the fourth conductive element.

Example 27 provides the IC structure of example 25, where a plane perpendicular to both the first direction and the second direction includes a portion of the second conductive element and a portion of the fourth conductive element.

Example 28 provides an IC structure, the IC structure including a first metallization layer including a first conductive line; and a second metallization layer including a second conductive line, the second metallization layer over the first metallization layer, where: the first metallization layer and the second metallization layer are stacked along a direction, and a projection of the first conductive line onto a plane perpendicular to the direction does not overlap with a projection of the second conductive line onto the plane.

Example 29 provides the IC structure of example 28, where the direction is a first direction, the first conductive line has a longitudinal axis substantially along a second direction substantially perpendicular to the first direction, the second conductive line has a longitudinal axis along a third direction, and the second direction is substantially parallel to the third direction.

Example 30 provides the IC structure of example 29, where the first metallization layer further includes a third conductive line, and a projection of the third conductive line onto the plane does not overlap with the projection of the second conductive line onto the plane.

Example 31 provides the IC structure of example 30, further including a third metallization layer including a third conductive line, where the second metallization layer is between the first metallization layer and the third metallization layer, and the third conductive line has a longitudinal axis substantially along a fourth direction, the fourth direction substantially perpendicular to the second direction.

Example 32 provides the IC structure of example 31, where a projection of the third conductive line onto the plane intersects the projection of the first conductive line onto the plane and the projection of the second conductive line onto the plane.

Example 33 provides the IC structure of example 32, further including a fourth metallization layer including a fourth conductive line, where the third metallization layer is between the second metallization layer and the fourth metallization layer, and the fourth conductive line has a longitudinal axis substantially along a fifth direction, the fifth direction substantially parallel to the fourth direction.

Example 34 provides the IC structure of example 33, where a projection of the fourth conductive line onto the plane does not overlap with the projection of the third conductive line onto the plane.

Example 35 provides the IC structure of example 30, further including a third metallization layer including a third conductive line, where the second metallization layer is between the first metallization layer and the third metallization layer, and the third conductive line has a longitudinal axis substantially along a fourth direction, the fourth direction substantially parallel to the second direction.

Example 36 provides the IC structure of example 35, where a projection of the third conductive line onto the plane does not overlap with the projection of the second conductive line onto the plane.

Example 37 provides the IC structure of examples 35 or 36, further including a fourth metallization layer including a fourth conductive line, where the third metallization layer is between the second metallization layer and the fourth metallization layer, and the fourth conductive line has a longitudinal axis substantially along a fifth direction, the fifth direction substantially perpendicular to the fourth direction. The IC structure of claim 37, where a projection of the fourth conductive line onto the plane intersects the projection of the first conductive line onto the plane, the projection of the second conductive line onto the plane, and the projection of the third conductive line onto the plane.

1. An integrated circuit (IC) structure, comprising:
a first metallization layer comprising a first conductive line;
a second metallization layer comprising a second conductive line; and
a third metallization layer comprising a third conductive line,
wherein:
the first metallization layer, the second metallization layer, and the third metallization layer are stacked along a direction,
the second metallization layer is between the first metallization layer and the third metallization layer,
a projection of the first conductive line onto a plane perpendicular to the direction is offset with respect to a projection of the third conductive line onto the plane, and
a projection of the second conductive line onto the plane intersects the projection of the first conductive line onto the plane and the projection of the third conductive line onto the plane.

2. The IC structure of claim 1, wherein the projection of the first conductive line onto the plane and the projection of the third conductive line onto the plane do not overlap.

3. The IC structure of claim 1, wherein the projection of the first conductive line onto the plane and the projection of the third conductive line onto the plane partially overlap.

4. The IC structure of claim 1, wherein the direction is a first direction, the first conductive line has a longitudinal axis along a second direction, the second conductive line has a longitudinal axis along a third direction, and the second direction is substantially perpendicular to the third direction.

5. The IC structure of claim 1, wherein the direction is a first direction, the first conductive line has a longitudinal axis along a second direction, the third conductive line has a longitudinal axis along a third direction, and the second direction is substantially parallel to the third direction.

6. The IC structure of claim 1, wherein the first metallization layer further includes a fourth conductive line, and a projection of the fourth conductive line onto the plane is offset with respect to the projection of the third conductive line onto the plane.

7. The IC structure of claim 6, wherein the first conductive line is substantially parallel to the fourth conductive line.

8. The IC structure of claim 1, further comprising a fourth metallization layer comprising a fourth conductive line, wherein the third metallization layer is between the second metallization layer and the fourth metallization layer, and the projection of the second conductive line onto the plane is offset with respect to a projection of the fourth conductive line onto the plane.

9. The IC structure of claim 8, wherein the projection of the third conductive line onto the plane intersects the projection of the second conductive line onto the plane and the projection of the fourth conductive line onto the plane.

10. The IC structure of claim 8, wherein the projection of the second conductive line onto the plane and the projection of the fourth conductive line onto the plane do not overlap.

11. The IC structure of claim 8, wherein the projection of the second conductive line onto the plane and the projection of the fourth conductive line onto the plane partially overlap.

12. An integrated circuit (IC) structure, comprising:
a first layer comprising a first conductive feature, the first conductive feature is elongated in a first direction;
a second layer over the first layer, the second layer comprising a second conductive feature; and
a third layer over the second layer, the third layer comprising a third conductive feature, the third conductive feature elongated in the first direction, wherein:
the first layer, the second layer, and the third layer are stacked along a second direction, and
in a superposed plane comprising a superposition of a first plane including a portion of the first conductive feature, a second plane including a portion of the second conductive feature, and a third plane including a portion of the third conductive feature, each of the first, second, and third planes oriented substantially perpendicular to the second direction, the portion of the first conductive feature and the portion of the third conductive feature occupy a larger portion of the superposed plane than either the portion of the first conductive feature or the portion of the third conductive feature individually, and the portion of the second conductive feature is joined with the portion of the first conductive feature and with the portion of the third conductive feature in the superposed plane.

13. The IC structure of claim 12, wherein the second conductive feature is elongated in a third direction, the third direction substantially perpendicular to the first direction.

14. The IC structure of claim 12, wherein the portions of the first conductive feature and the third conductive feature in the superposed plane are separated.

15. The IC structure of claim 12, wherein the portions of the first conductive feature and the third conductive feature in the superposed plane are joined.

16. The IC structure of claim 12, further comprising a fourth layer comprising a fourth conductive feature, wherein the superposed plane further comprises a superposition of a fourth plane, the fourth plane oriented substantially perpendicular to the second direction and including a portion of the fourth conductive feature, and the portions of the second conductive feature and the fourth conductive feature occupy a larger portion of the superposed plane than either the portion of the second conductive feature or the portion of the fourth conductive feature individually.

17. An integrated circuit (IC) structure, comprising:
a first conductive element extending substantially along a first direction;
a second conductive element extending substantially along a second direction; and
a third conductive element extending substantially along the first direction,
wherein:
the second conductive element is between the first conductive element and the third conductive element,
at least one plane substantially perpendicular to both the first direction and second direction includes a portion of the first conductive element and does not include any portion of the third conductive element, and
at least one plane substantially perpendicular to both the first direction and a second direction includes a portion of the third conductive element and does not include any portion of the first conductive element.

18. The IC structure of claim 17, wherein no plane perpendicular to both the first direction and the second direction includes both a portion of the first conductive element and a portion of the third conductive element.

19. The IC structure of claim 17, wherein a plane perpendicular to both the first direction and the second direction includes a portion of the first conductive element and a portion of the third conductive element.

20. The IC structure of claim 17, further comprising a fourth conductive element, wherein the third conductive element is between the second conductive element and the fourth conductive element, at least one plane substantially perpendicular to both the first direction and the second direction includes a portion of the second conductive element and does not include any portion of the fourth conductive element, and at least one plane substantially perpendicular to both the first direction and the second direction includes a portion of the fourth conductive element and does not include any portion of the second conductive element.
